(19) United States
(12) Patent Application Publication
(10) Pub. No.: US 2009/0251867 A1
(43) Pub. Date: Oct. 8, 2009

(54) RECONFIGURABLE, MODULARIZED FPGA-BASED AMC MODULE

(76) Inventors: Viswa N. Sharma, San Ramon, CA (US); William Chu, Elmsford, NY (US)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(21) Appl. No.: 12/248,719

(22) Filed: Oct. 9, 2008

Related U.S. Application Data
(60) Provisional application No. 60/978,650, filed on Oct. 9, 2007.

(51) Int. Cl. H05K 1/14

(52) U.S. Cl. 361/737

(57) ABSTRACT

A standard compliant printed circuit base boards or modules for telecommunications, networking and computer equipment electrically and mechanically couples with reusable modular daughter cards to provide application-specific functionality within spatial limitations as required to comply with industry specifications. In particular, an Advanced Mezzanine Card (AMC) Specification compliant printed circuit board is configured for releseably coupling with one or more reusable daughter cards to provide reconfigurable, modularized and scalable electrical functionality in an AMC form factor.

### RELATED APPLICATION

This application claims the benefit of U.S. Provisional Application No. 60/978,650, filed Oct. 9, 2007, which is hereby fully incorporated herein by reference.

### FIELD OF THE INVENTION

The present invention relates generally to telecommunications, networking and computer equipment (“communication system”) and specifically, but not exclusively, to an apparatus and method for managing input and output of network traffic to one or more devices in a communication system.

### BACKGROUND OF THE INVENTION

Over the years, the telecom, datacom and computing systems marketplace has experienced a divergence from product designs predicated upon low unit volume, high price, proprietary system architecture towards standards-based, flexible, extendable solutions built using commercial off-the-shelf (COTS) technology. Migration to this new paradigm is partly driven by the need to respond to an ever evolving network infrastructure wrought by rapid innovation in this particular market space whilst attempting to maintain low operating and capital expenditures. Catalyzing this shift are standards based technologies that adhere to specifications defined by industry sponsored standards making bodies such as the Advanced Telecom Computing Architecture (or AdvancedTCA™ (hereinafter “ATCA”) and the Micro Telecom Computing Architecture (MicroTCA).

The Advanced Telecom Computing Architecture (or AdvancedTCA™ (hereinafter “ATCA”), exemplifies an industry sponsored specification that is gaining wide acceptance by both, suppliers and end-users to construct ATCA standard-compliant solutions. The ATCA Base Specification, PIGMG 3.0 Revision 1.0, ratified in Dec. 30, 2002 (hereinafter “the ATCA specification”), is a series of industry standards that define scalable, standardized platform architecture to extend COTS to a broad spectrum of products from component vendors. ATCA compliant components and systems embody interoperable ATCA technology such as physical format, system management and software designed to deliver cost effective, reduced time-to-market, off-the-shelf solutions that can be incorporated into products ranging from high-availability, carrier-grade telecom, storage, and computing applications. ATCA is sponsored by the PCI (Personal Computer Interconnect)—Industrial Computer Manufacturers Group (PICMG®), a major industry standards body. The ATCA specification defines an open electromechanical architecture of a modular platform that may be constructed from commercial off-the-shelf components. The electromechanical architecture encompasses the rack and shelf (chassis) mechanical form factors, power parameters, cooling characteristics, core backplane fabric interconnects and system management architecture to enable the construction of a modular platform that is capable of receiving a multiplicity of ATCA compliant modular plug-in circuit boards (ATCA carrier cards) suitable for the telecommunication, data center and computing industries.

The ATCA compliant modular plug-in circuit boards (“carrier boards”) feature an open electromechanical architecture also defined by the ATCA specification. The ATCA base specification together with other associated specifications define multiple fabric connections and support multiple protocols for control and data plane communications including Ethernet, Fibre Channel, InfiniBand, StarFabric, PCI Express, and RapidIO®. The payload of the carrier board includes mezzanine cards, such as the PICMG® Advanced Mezzanine Card (AdvancedMC or AMC™) (more fully described below) that implement user defined functionality and are generally coupled to the front (alternately “carrier”) board in parallel to a major surface of the board.

The members of PICMG have also ratified the MicroTCA specification (MicroTCA.0 R1.0, Jul. 6, 2006). MicroTCA-standards based systems are described in the publicly available short form specification derived from the PICMG® MTCA.0 Micro Telecommunications Computing Architecture (MicroTCA.0) specification. (Note: MicroTCA and the μTCA are trademarks of PICMG. AdvancedTCA and AdvancedMC are registered trademarks of PICMG). The MicroTCA specification utilizes the PICMG AdvancedMC form-factor and management infrastructure for mezzanine blades, as defined in the ATCA specification, to define the standardized elements needed to implement a MicroTCA Shelf (or “Shelf” which is also known as the chassis), including power modules, cooling elements, connectors, interconnects, backplane, MicroTCA Carrier Hub (MCH) and the sub-rack. The Shelf may be configured to realize diverse small foot-print, low-cost, flexible, and scalable platforms comprised entirely of AdvancedMC modules and interoperable components and systems. The thrust of MicroTCA is the reuse of technology defined by the AMC standard so that an AMC card (or module) can be used with either an ATCA carrier board or a “MicroTCA Carrier”. The “MicroTCA Carrier” as the term is used in MicroTCA, refers to the elements of a MicroTCA Shelf including, among others, cooling and power delivery elements, a backplane with clock, fabric, power and management interconnects, and centralized hardware management that collectively emulate the requirements of the ATCA carrier board and can nominally support up to 12 AMC modules. Each AMC module plugs directly into the MicroTCA backplane instead of an ATCA based carrier board. A MicroTCA system consists of at least one AMC card. Additionally, a MicroTCA system also consists of at least one MicroTCA-specific module not defined by the AMC.0 specification. For example, a MicroTCA system consists of at least one AMC card and at least one MicroTCA-specific AMC-sized card called a MicroTCA Carrier Hub (MCH). The MCH combines the control and management infrastructure and the interconnect fabric resources needed to support up to 12 AMC. The MCH also contains IPMI software for managing key chassis functions, as well as clocking AMC daughter cards for different applications.

Another MicroTCA-specific component is the power module, which fits in the same form factor as an AMC card. Thus configured, the MicroTCA form factor targets communications equipment ranging from pole mounted devices to core routers and IP-gateways, radio base stations and switching centers.

It will be appreciated that an AMC module is common to both, the ATCA and MicroTCA. The AdvancedMC card/module is defined by the PICMG® Advanced Mezzanine Card (AdvancedMC or AMC™) base specification, PIGMG AMC.0, Revision 2.0, published Dec. 28, 2006 (hereinafter referred to as the AMC.0 specification, the entire contents of which are incorporated herein by reference). AMC cards add versatility to the modularity provided by the ATCA specification. The AMC architecture supports a number of transfer protocols with varying band widths as described in the subsidiary PICMG standard AMC3.0 for example. AMC cards extend the functionality of the ATCA carrier boards and permit multiple vendors to build technology solutions for transmission and switching equipment and allow these technology solutions to be used in multiple applications and in multiple vendor product lines.

The AMC specification defines the base-level mechanical, management, power, thermal, interconnect (including I/O) and system management requirements for hot-swappable, field-replaceable, add-on mezzanine cards (or modules) (alternately, the AMC cards or AMC modules) which may be hosted by an ATCA or a proprietary carrier board. The AMC architecture supports a number of transfer protocols with varying band widths as described in subsidiary PICMG standards. For example, the AMC3.0 extension to the AMC Specification layers Serial Attached SCSI (SAS), Serial ATA (SATA) and Fibre Channel interfaces for storage devices on the base AMC.0 specification. PICMG 3.x series specifications also define standards for different kinds of protocols. For example, the PICMG® 3.4 Specification defines the PCl-Express signals to be used by a motherboard that is connected with a PICMG 3.0 compliant backplane. PCI and PCI-Express protocols are used extensively in the ATCA Specification, for example, in terms of the specifications for signals and connectors. Thus, one of the functionalities provided by the AMC module may be the bridging between dissimilar protocols for communications to and from a communication network and an ATCA or MicroTCA compliant network device connected to the communication network, for instance. In this regard, the AMC card may be configured as a line card which provides data path support by performing protocol conversion on data entering or leaving the network device. The AMC specifications impose limitations on the geometry of the AMC module and thereby on the silicon and associated materials that may be disposed on a single module. For example, there are six different form factors defined in the AMC specification which include two AMC module widths (W): the single width module (73.5 mm) and a double width module (148.5 mm); three heights (H) or thicknesses: compact (13.8 mm), mid-sized (18.96 mm) and full-sized (28.95 mm); and a single depth (D) (181.5 mm). These geometrical restrictions are reflected in the form factor of the card and on the enveloping volume associated with the card. The form factor and the enveloping volume define the metes and bounds of the allowable heights of components and the number (or component density) that may be placed on the printed circuit board (PCB). Each AMC Module is received into an AMC Connector, and because it is a mezzanine card, it is seated with its opposed pair of planar major surfaces parallel to the host carrier card and configured for high-speed, packet-based serial communications between the AMC card and the carrier board. One of the planar surfaces faces the mezzanine card is generally referred to in the Specification as component side 1 and the other opposed side is referred to as component side 2.

Component side 1 is disposed proximate a major surface of the host carrier card. Electronic circuitry on the AMC card may be disposed on both, component side 1 and component side 2. However, due to geometry restrictions, the total mechanical envelope (or volume) on both component side 1 and component side 2 is very limited, which imposes significant limitations on the silicon and other hardware that may be placed on the AMC module and therefore on the functionality that the AMC module can be designed to deliver.

Some of these limitations may be overcome by exploiting the carrier board geometry—for example, the AMC specification refers to three types of carrier board configurations—conventional, cutaway and hybrid. It will be appreciated that exploiting carrier board configurations, such as using the cutaway or hybrid configuration, is essentially relinquishing carrier board real-estate (by cutting out a portion of the carrier board, for example) to incrementally extend the volumetric envelope available for silicon on component side 1 of the AMC module. Conventionally, AMC cards are designed with custom or semi-custom, or application specific hardware and circuitry to deliver specific functionality and performance in cooperation with a given configuration of a base carrier card. It is not uncommon to find an AMC card that features a particular I/O interface or other physical or circuit elements appropriate for the functionality and performance required of the card and which can only be changed by redesign and remanufacture of the card. In effect, these AMC cards cannot, in general, be reconfigured for other applications because they have to meet stringent design and test requirements to meet applicable standards. Quite often, such AMC cards are used with test platforms for rapid design validation or are required to operate in rapidly changing technological environments that accelerate obsolescence.

In other applications, AMC cards may be configured as port cards. Typically, the port card may provide at least one physical interface between the communication system and the communication link (or medium) and may be adapted to receive and transmit signals to and from the communication system. Generally, each port is configured for a specific purpose and with various attributes so as to be capable of supporting a particular signaling and control protocol such as, Ethernet, PCI-Express, Serial Rapid I/O, OC-192 and such like. Each port presents a physical interface that determines how data is actually moved to and from the system and a communication medium. The interface may be an optical interface to fiber optic transmission systems (FOTS) or an electrical interface that couples the system to a copper cable/circuit or similar physical medium. Conventional port modules implement one or more specific serial communication ports in the form of physical transceivers disposed on a “front panel” or other portion of the port module that is accessible to the physical media. Each port module (such as the AMC based module) also provides a backplane interface via which the AMC card provides connectivity between the physical medium coupled to it at the front panel and the rest of the communication system using a pre-defined communication protocol dictated by the backplane and the rest of the communication system. Prior art port cards typically present a pre-defined set of physical media interfaces at which signal ingress and egress to an external communication media occur and a pre-defined backplane interface through which data is transferred to and received from the communication system. Such an arrangement can constrain the I/O and I/O related functional capability of the port module making the port card suitable only for a specific network and/or system infrastructure and precluding adaptation to changed circumstances. For example, increased demand for connectivity that translates into a change in the type, number of I/O resources or that requires additional or different pre-post processing of I/O related data may not be possible to accommodate without actually changing-out the port module.

It would be advantageous to provide port modules (such as a port module in an AMC form factor) that can be reconfigured to enable new applications, I/O resource needs, or be made backward-compatible to earlier versions of the standard but without the detriment of lengthy design and fabrication lead times or non-recurring engineering costs customarily involved in designing an AMC based solution from the ground up. As the demand for compact network devices with enhanced functionality continues to rise, and as time-to-market shrinks it would be advantageous to further leverage the availability of COTS cards/modules, such as the cards/modules exemplified by AMC compliant cards, to manage network traffic to and from a communication system.

### SUMMARY OF THE INVENTION

The present invention relates generally to telecommunications, networking and computer equipment and specifically, but not exclusively, to a standards compliant printed circuit base boards or modules that electrically and mechanically couple with reusable modular daughter cards to provide application-specific functionality within spatial limitations as required to comply with industry specifications. In particular, the present invention relates to an Advanced Mezzanine Card (AMC) Specification compliant printed circuit board configured for releseably coupling with one or more reusable daughter cards to provide reconfigurable, modularized and scalable electrical functionality in an AMC form factor.

Embodiments of the present invention recognize that it would be advantageous to provide AMC cards that can be reconfigured to enable new applications or be made backward-compatible to earlier versions of the standard but without the detriment of lengthy design and fabrication lead times or non-recurring engineering costs customarily involved in designing an AMC based solution from the ground up. As the demand for compact network devices with enhanced functionality continues to rise, and as time-to-market shrinks it would be advantageous to further leverage the availability of AMC cards having a wide variety of form factors by extending the real-estate available for silicon and circuit elements so as to enable each of the cards to accommodate a rich mix of circuit elements and circuit topologies in a modular, extendable format capable of supporting different application architectures to address the needs of diverse segments of the computer and telecommunications marketplace.

### BRIEF DESCRIPTION OF THE DRAWINGS

FIG. 1 is a perspective view of AMC modules depicting AMC specification defined form factors.

FIGS. 2A and 2B are perspective views of a ATCA specification based carrier card configured to and receiving the AMC modules depicted in FIG. 1.

FIGS. 3A and 3B illustrate AMC module orientations in a conventional ATCA specification compliant carrier cards.

FIG. 4A is a block diagram representation of a MicroTCA specification based platform.

FIGS. 4B and 4D illustrate a mechanical cabinet and backplane for housing a MicroTCA specification based platform according to FIG. 4A.

FIGS. 4C and 4E are illustrative of the mechanical dimensions of a AMC module within a slot of the mechanical cabinet of FIG. 4B.

FIG. 5 is a functional block diagram representation of an AMC module according to an exemplary embodiment of the present invention.

FIGS. 6A and 6B depict a perspective and a side view of an exemplary circuit card module according to the present invention.

FIGS. 7A thru 7D represent perspective views of exemplary embodiments of a base module according to the present invention including an exploded view of a base module in FIG. 7A.

FIGS. 7E and 7F illustrate a top view and a side view of an exemplary base module in accordance with the present invention.

FIGS. 7G and 7H are perspective views of component side_2 of an exemplary base module and an assembled circuit card module in accordance with the present invention.

FIG. 7I is a schematic representation of an exemplary circuit card module illustrating a PHY card and a daughter card with co-processor support

FIGS. 8A and 8B are perspective views of exemplary I/O PHY card according to the present invention.

FIGS. 8C-8F are schematic representations of exemplary connector configurations on an exemplary I/O PHY card according to the present invention.

FIG. 8G illustrates the location of connectors on an exemplary base board module according to the present invention.

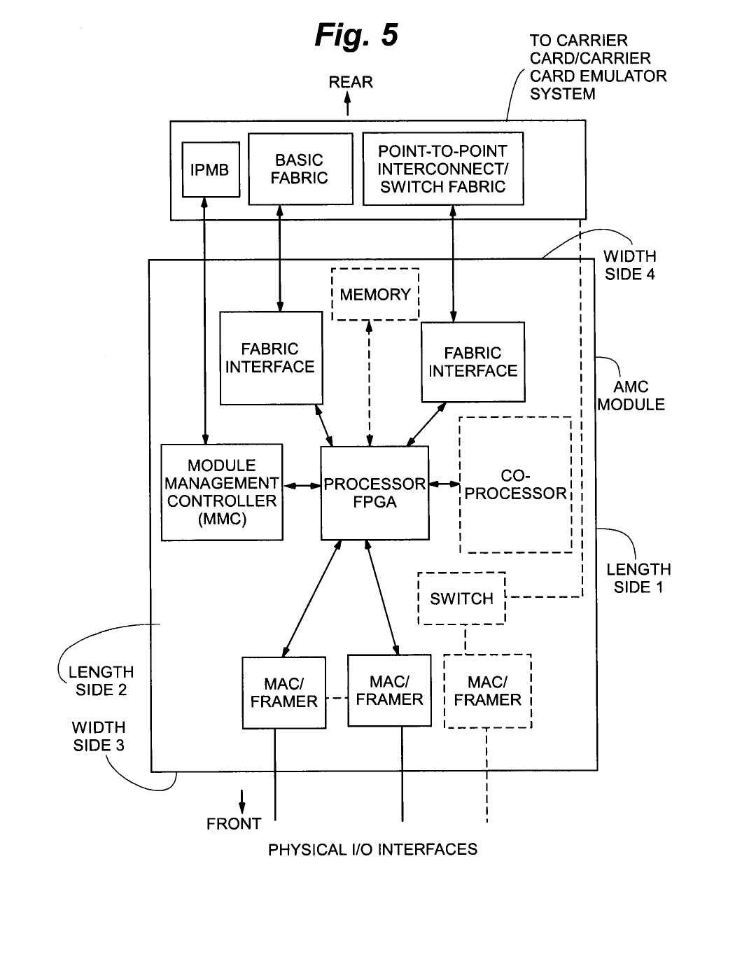

FIG. 5H illustrates exemplary connectors in accordance with the present invention.

FIGS. 9A and 9B are exemplary embodiments of daughter cards and their assemblage on a base board module according to the present invention.

FIGS. 10A and 10B are perspective and exploded perspective views respectively of an exemplary circuit card module illustrating a I/O PHY card according to the present invention.

FIGS. 11A and 11B exemplify a circuit card module with a single daughter card extending towards the rear of the circuit card module shown in top view and side view respectively according to the present invention.

FIGS. 12A and 12B depict a perspective and side views of a circuit card module with dual (front and rear) extending daughter cards according to the present invention.

FIGS. 13A thru 13D represent top, side, perspective and exploded perspective views of a circuit card module with a I/O PHY module and a rear daughter card according to the present invention.

FIGS. 14A and 14D represent a top, side, perspective and exploded perspective views respectively of a circuit card module with dual daughter cards according to one embodiment of the present invention.

FIG. 14E is a schematic representation of the circuit card module of FIG. 14 according to the present invention.

FIGS. 15A thru 15D represent respectively a top view, a side view, a perspective view and an exploded perspective view of a circuit card module with a single I/O PHY card provided with some features of a non-PHY daughter card according to the present invention.

FIGS. 16A and 16B illustrate a top view and a side view of a single daughter card (non-PHY) extending substantially from the front panel and the card edge connector according to the present invention.

FIGS. 17 and 18 are a high level schematic and a detailed level schematic of a circuit card module according to one embodiment of the present invention.

### DETAILED DESCRIPTION OF THE DRAWINGS

In the following description, reference is made to the accompanying drawings which form a part hereof and which illustrate several embodiments. In the following detailed description, numerous specific details are set forth to provide a full understanding of the present invention in terms of descriptions of exemplary embodiments framed in the context of the ATCA, MicroTCA and AMC standards. However, it will be understood that this approach does not limit the use of the principles and teachings disclosed herein to ATCA, MicroTCA, AMC or other standards compliant equipment. One skilled in the relevant art will recognize that the invention can be practiced without one or more of the specific details, or with other methods, components, materials, specifications, etc. In other instances, well-known structures and techniques have not been shown in detail so as to avoid unnecessarily obscuring the present invention.

In general, the present invention comprises an apparatus and method for managing input and output of network traffic to one or more devices in a communication system. In an exemplary embodiment, the apparatus comprises a circuit card module configured for being releasably received on a carrier board as a mezzanine card or in a system that generally emulates the environment of the carrier board and acts as a host to the circuit card module. Without limiting the scope of the invention, the carrier board module, standing alone or in combination with other carrier board modules and other devices, may be configured as a portion of a communication system that receives and transfers data and/or control signals from and to a medium external to the communication system following at least one data-path.

In the exemplified embodiment, the circuit card module is disposed in at least one data-path and serves to mediate communications between the communication system and the external medium. In one embodiment, the circuit card module comprises a circuit card (alternately “base card” or “base module”) and at least one daughter card. Each of the circuit card and the at least one daughter card may be considered to be sub-assemblies for ease of description but not by way of limitation. The circuit card (or base card) is designed to electrically and mechanically couple with at least one daughter card via one or more connectors located on the base card. The daughter card can be inserted into and removed out of electrical connection with the base card via the connector or connectors. The circuit card module, as a whole or in sub-assembly form, may conform with one or more industry standards. Exemplary embodiments of the present invention contemplate a physical and functional portioning of the circuit card module that preserves compliance with applicable industry standards for the circuit module as a whole while facilitating customization to allow delivery of application specific functionality, modularization that permits reconfiguration of the custom functionality by simply swapping out the daughter cards, and maximization of functionally that can be deployed by increasing the circuit density possible within the strict dimensional specifications prescribed by the applicable industry standards.

Reference will now be made to the figures to describe the various embodiments of the present invention.

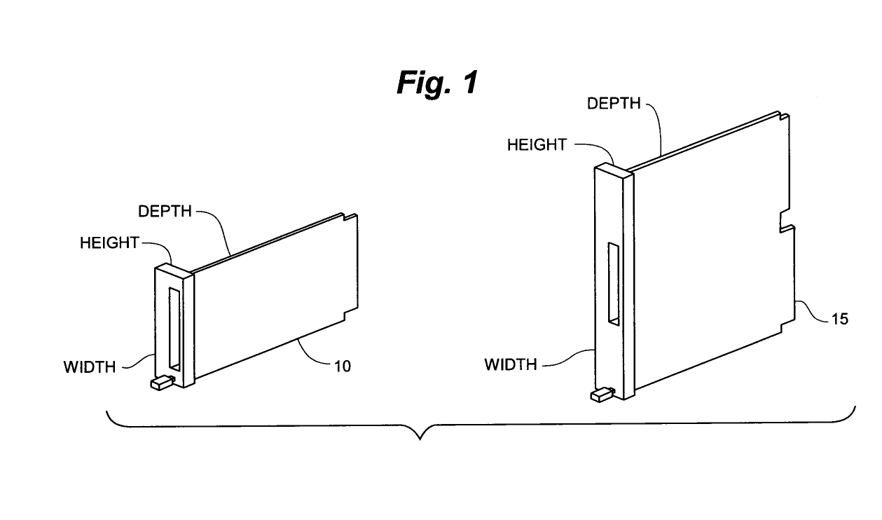

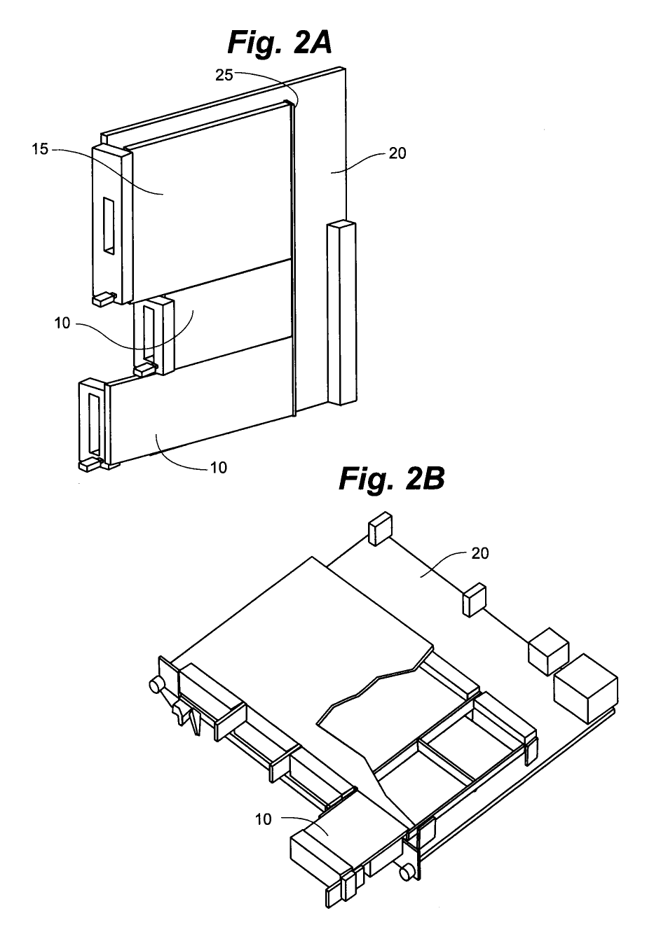

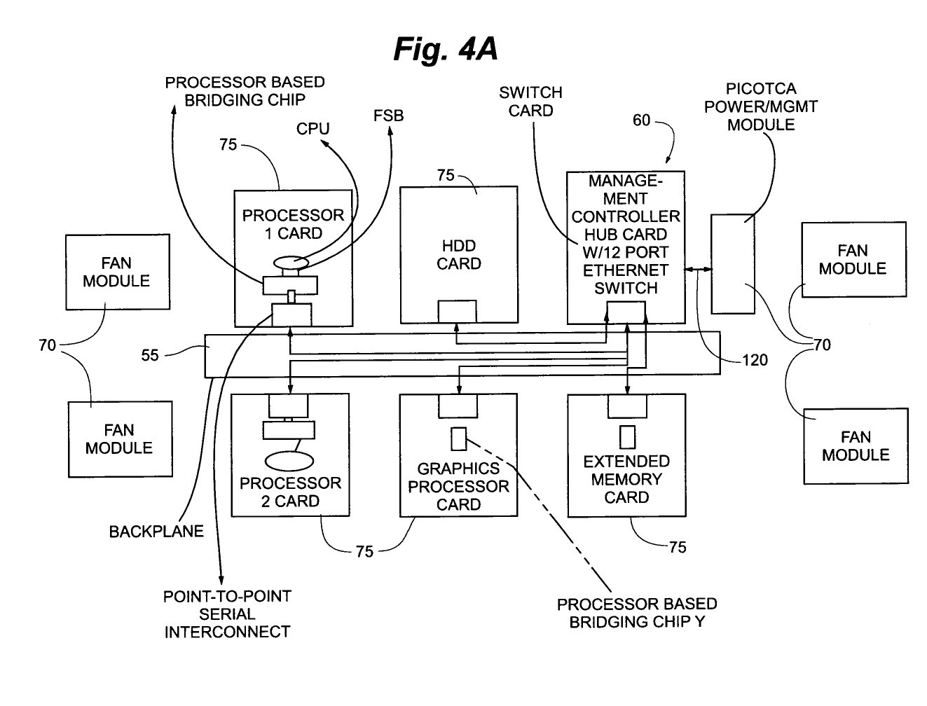

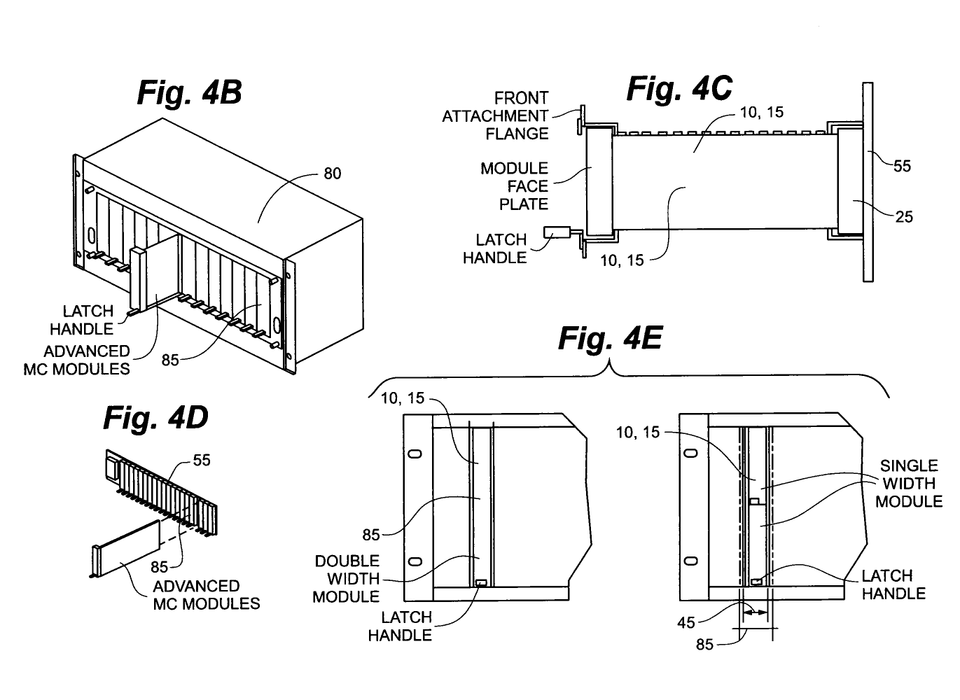

For ease of description but not by way of limitation, an exemplary embodiment of the present invention will be described with reference to a circuit card module that conforms to the AMC specification and is received within a communication system configured to comply with the MicroTCA specification. Accordingly, in one exemplary embodiment of the present invention, the circuit card module 100 of the present invention is basically a AMC specification compliant module and therefore capable of being received in and interoperating with other modules within ATCA and MicroTCA compliant platforms. Compliance with the AMC specification requires that the circuit card module 100 conform to certain threshold mechanical and electrical requirements as will be described next with reference to the illustrations of FIGS. 1, 2A, 2B, 3A, 3B, 4A thru 4E. FIGS. 1, 2A, 3A and 3B are taken or derived from the AMC Specification. FIGS. 2B, 4B, 4C, 4D and 4E are derived from the MicroTCA Specification.

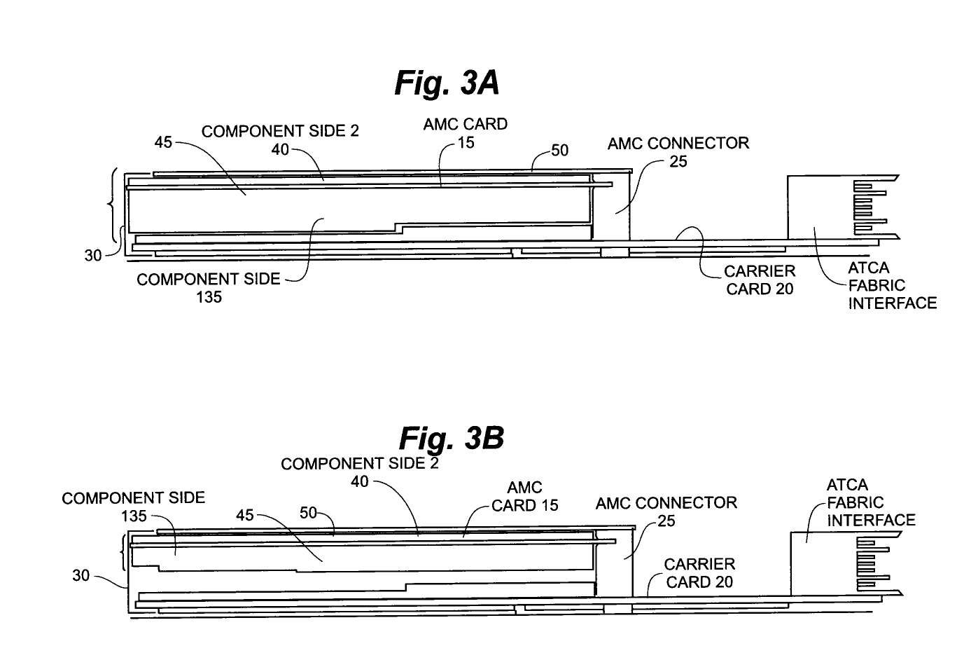

FIG. 1 illustrates a single-width, full-height conventional AMC module 10 and a double-width, full-height conventional AMC module 15. Each of the aforementioned modules (10, 15) may be a half-height module without falling outside the scope of the AMC specification. FIGS. 2A and 2B depict a perspective view of an exemplary carrier board 20 defined by the ATCA Base Specification, and which is configured to receive a plurality of AMC cards (10, 15) in a mezzanine arrangement. Carrier board 20 is designed to allow the insertion and removal of a plurality of AMC modules (10, 15) from a front side of the carrier board 20 with each AMC module being received within and placed in mechanical and electrical connection with an AMC connector 25 located on the board 20. FIGS. 3A and 3B are side views of the carrier board 20 of FIG. 2 with AMC modules (10, 15) in a fully inserted configuration within AMC connector 25 located on carrier board 20. FIGS. 3A and 3B illustrate, with respect to each AMC card 10, 15, a component side_1 35 and a component side_2 40 representing opposed major surfaces of the card. A first and second component volumes 45, 50 extend from component side_1 35 and component side_2 40 respectively. The extent of each component volume is defined by the AMC specification and represents a spatial bound within which all components, circuitry and other material disposed on the major surface associated with the particular component volume must remain in order to be comply with the strict dimensional restrictions of the AMC Specification. It will be appreciated that component volumes play a significant role in circumscribing the circuit density and therefore the functionality that can be configured onto an AMC module. FIG. 4A is another exemplary system 60 within which a conventional AMC card may be utilized. System 60 does not feature a carrier card such as the one described above. Instead, system 60 emulates the environment provided by a carrier card sufficient to host one or more conventional AMC modules as provided for in the MicroTCA specification.

As illustrated in FIGS. 4A, 4B and 4D, system 60 (shown in block diagram form in FIG. 4A) generally includes a backplane 55, a MicroTCA Carrier Hub (MCH) 65, at least one AMC MicroTCA specific module (CU and PM) 70 and at least one AMC payload module 75 received in and coupled to connectors on the backplane in the rear of system 60 in an arrangement that facilitates insertion and removal of the AMC modules from the front of the system 60. The backplane is typically configured as a printed circuit board (PCB) with interconnects for transferring signals (or data streams) to and from modules connected to the backplane. The MicroTCA backplane provides an I2C based Intelligent Platform Management Interface (IPMI) for chassis management and control of the AMC modules connected to the backplane, as well as the cooling units and power modules that constitute MicroTCA specific, non-payload modules of the system. The MicroTCA backplane also includes at least a portion of the plurality of fabrics and interconnects that provide a pathway for signals/data transfer between the modules connected to the backplane.

FIGS. 4B and 4D depict a multiple slot mechanical cabinet 80 or rack designed and dimensioned to conform to the MicroTCA specification and to house system 60. The mechanical cabinet 80 is capable of receiving and housing front-loaded conventional AMC modules retained in AMC connectors on the backplane 55. FIGS. 4C and 4E illustrate the mechanical configuration of a typical slot 85 of mechanical cabinet 80. The potential component volume available on component side_1 35 of AMC module 10, 15 in slot 85 is indicated by reference numeral 45 in FIG. 4E. For each AMC module 10, 15, Input/Output (I/O) may be implemented through either the faceplate (alternately “front panel”) at a front side of the AMC module 10, 15 or the AMC connector 25.

FIG. 5 is a block diagram representation of the functionality that an exemplary AMC module 10, 15 can feature within the scope of the AMC specification. Compliance with the AMC specification requires each AMC module to provide at least 1) an intelligent module management controller (MMC) in order to enable communication with the IPMI shelf controller and support a minimal set of IPMI commands to access information such as module power requirements, power supply health, temperature and other status; 2) an IPMI interface 3) a high-speed rear-connector serial interface to the baseboard or the backplane as applicable to support high-speed interconnect options including PCI Express, Gigabit Ethernet and RapidIO; 4) a power supply rail; and 5) system clock and clock distribution. Neither the AMC specification nor any of the other above-cited standards—i.e. ATCA or MicroTCA, describe the applications that can be realized within the scope of the specifications. Nor do any of the specifications provide design details of any standards-based architecture—ATCA, MicroTCA or AMC to enable the effectuation of specific functionality. Thus, a wide range of functionality is achievable and readily implemented within the power budget and size envelope of AMC modules.

For example, the circuit card module may be a line card which connects to a network or it may be a service card that operates locally within the system without interacting with an external network. The circuit card module 100 may carry general-purpose processors, FPGA-based hardware accelerators, network processors, digital signal processors (DSPs), memory, hard disk drives, clock generators and drivers, intelligent I/O, and radio modules.

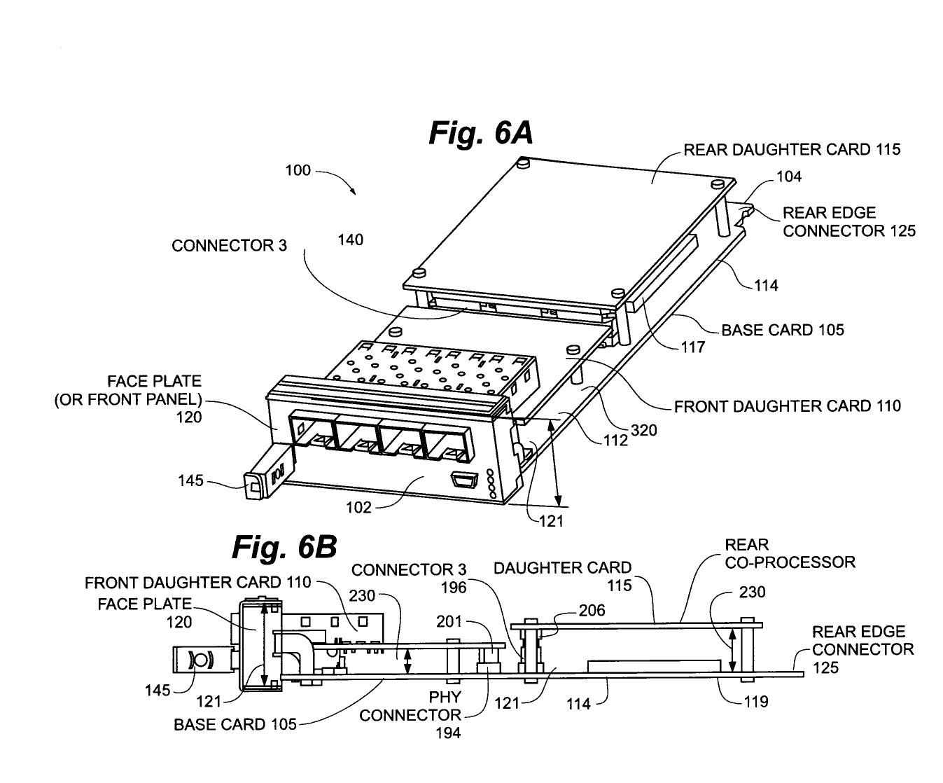

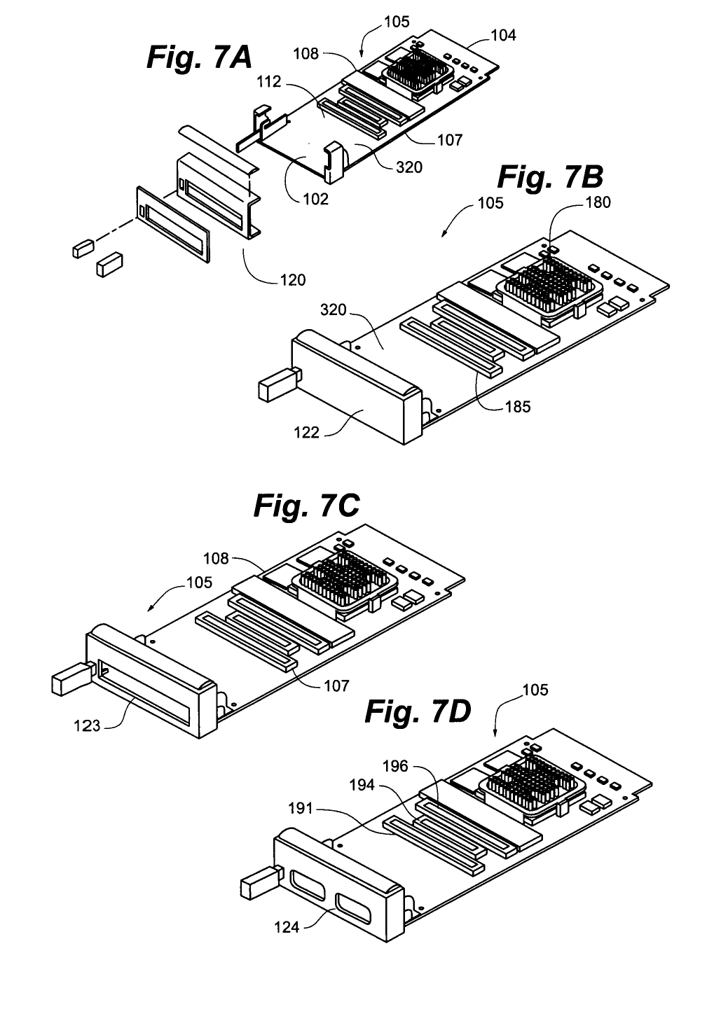

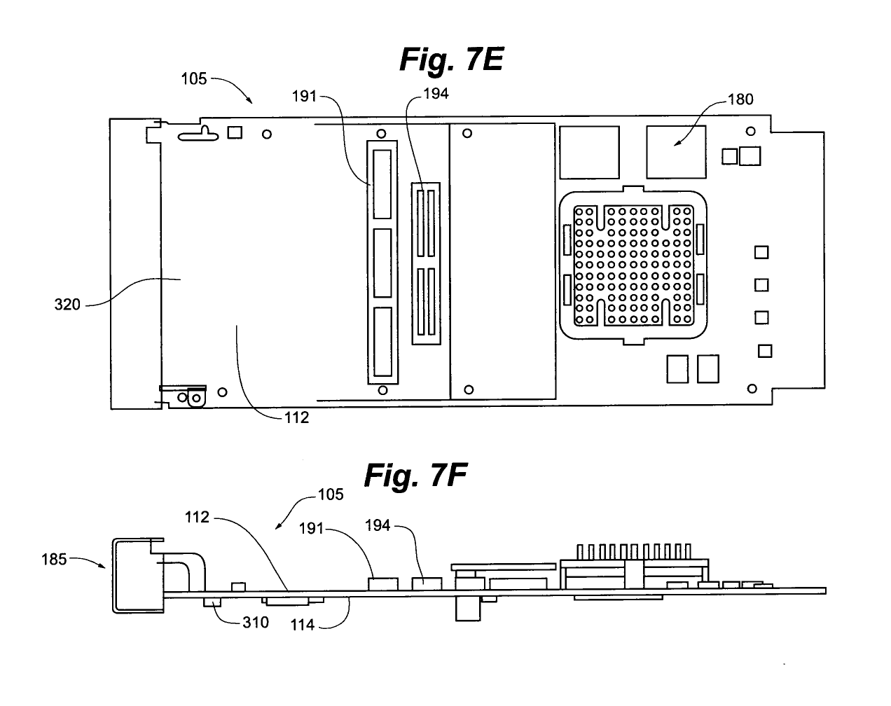

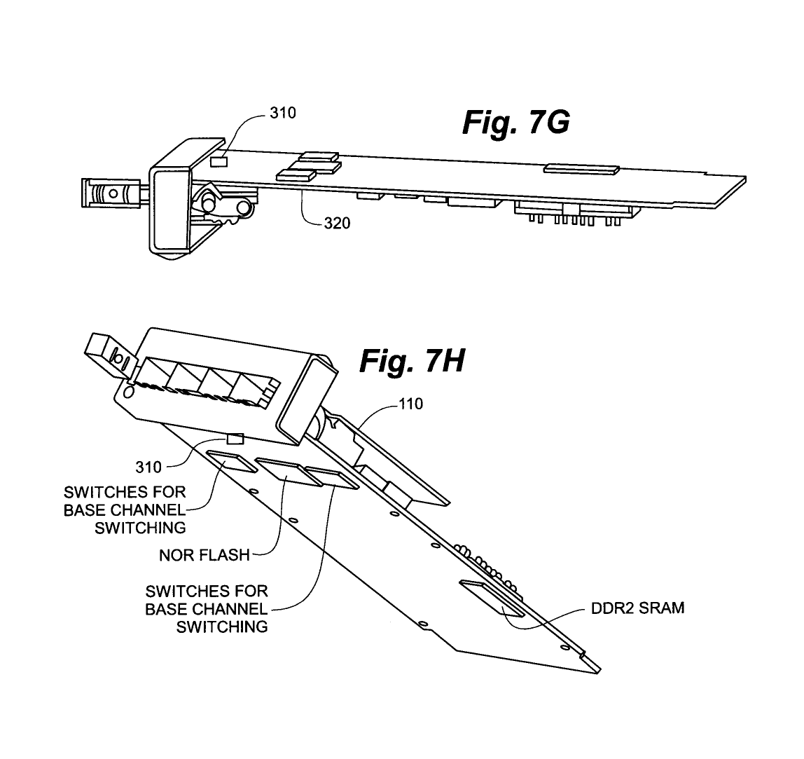

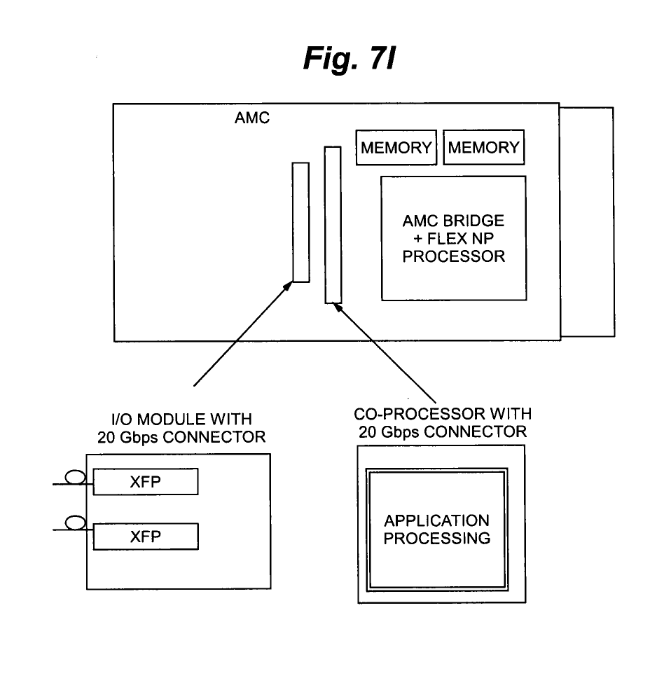

Referring now to FIGS. 6A, and 6B an assembly according to one embodiment of the present invention generally includes a circuit card module 100 comprising a base card 105 and one or more daughter cards 110, 115. Base card 105 (alternatively “Base board” 105) includes a front side 102 spaced from a rear side 104 with first and second lengths 107, 108 extending there between as more clearly depicted in FIG. 7A. Front side 102, first length 107, rear side 104 and second length 108 form the bounds of first and second opposed base board areas 112, 114 associated with component volumes 117, 119 respectively. Front side 102 is coupled to a face plate 120 of height 121 and rear side 104 is configured into a card edge connector 125 capable of being slidingly inserted and removed from a female connector 127 (not shown). In the embodiment illustrated in FIGS. 7A thru 7D, base card 105 generally shares substantial mechanical similarity to the AMC module 10 in FIGS. 1, 2A, 2B, 3A and 3B with the front side and rear sides 102, 104 respectively generally corresponding to the “width” dimension, the first and second lengths 107, 108 generally corresponding to the “depth” dimension and the face plate height 121 generally corresponding to the “height” dimension as more clearly illustrated in FIG. 2B for example. First and second opposed base board areas 112 and 114, in the illustrative embodiment, generally correspond to component side_1 35 and a component side_2 40 respectively of AMC module 10. Base board areas 112, and 114 are associated with component volumes 45, 50 respectively as illustrated in FIGS. 3A and 3B and defined by the AMC specification in relation to AMC module 10.

In the illustrative embodiment of FIGS. 7A-7D, circuit card module 100 is based on a single-width 102, 104 form factor and may be either full-height and mid-size heights 121 that is front-loadable into slot 85 of mechanical cabinet 80, for instance. In this configuration, circuit card module 100 as a whole may be compliant with and substantially correspond to the mechanical and electrical standards prescribed in the AMC specification as will be described below. However, it will be understood that the mechanical dimensions presented above are only by way of exemplification of the circuit card module 100 of the present invention and not by way of limitation. The circuit card module 100 may be shaped and dimensioned to conform to other mechanical form factors and dimensions unrelated to the AMC specification and remain within the scope of the present invention.

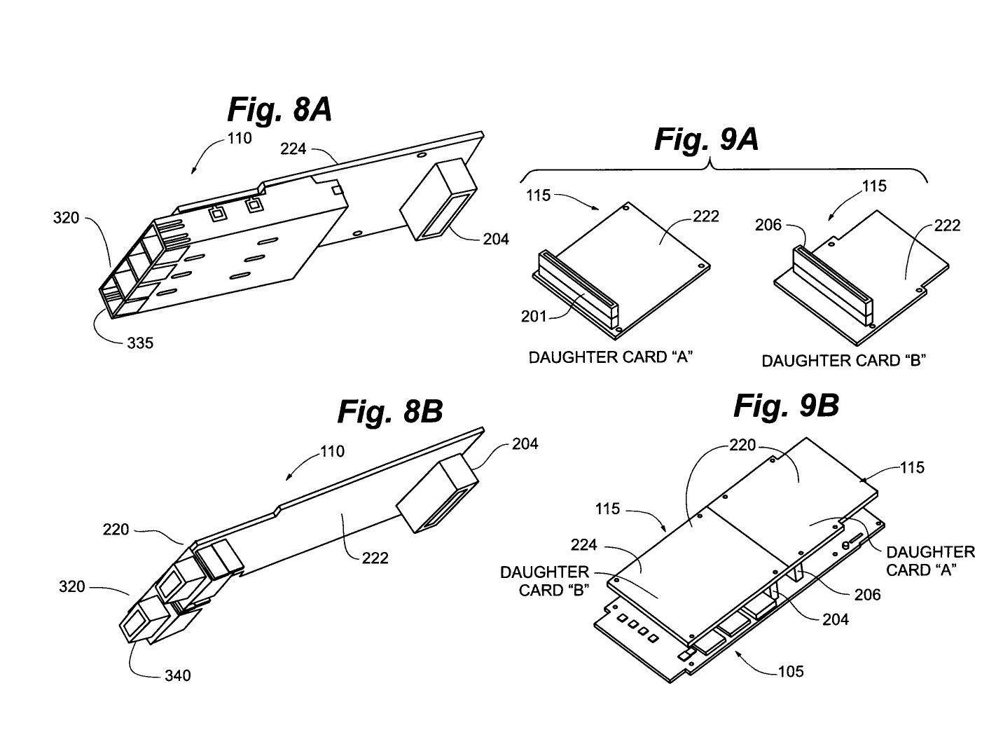

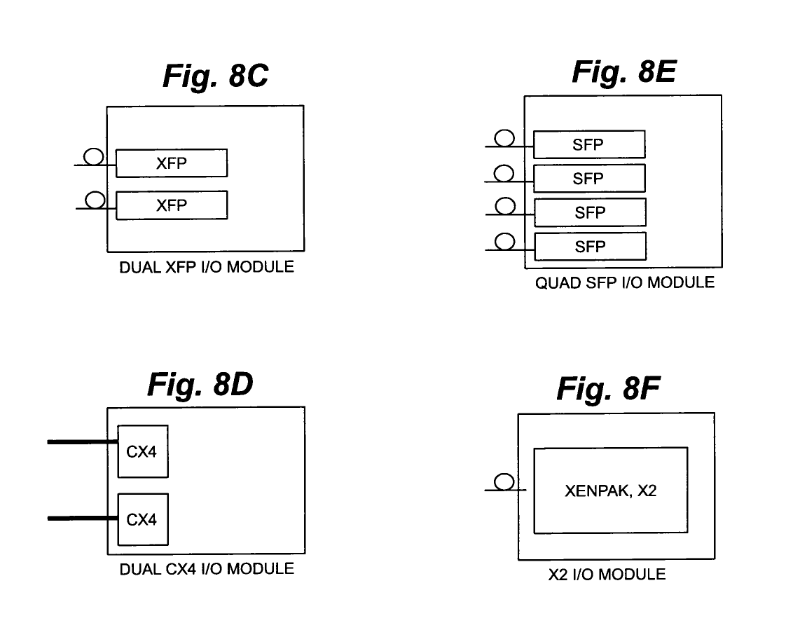

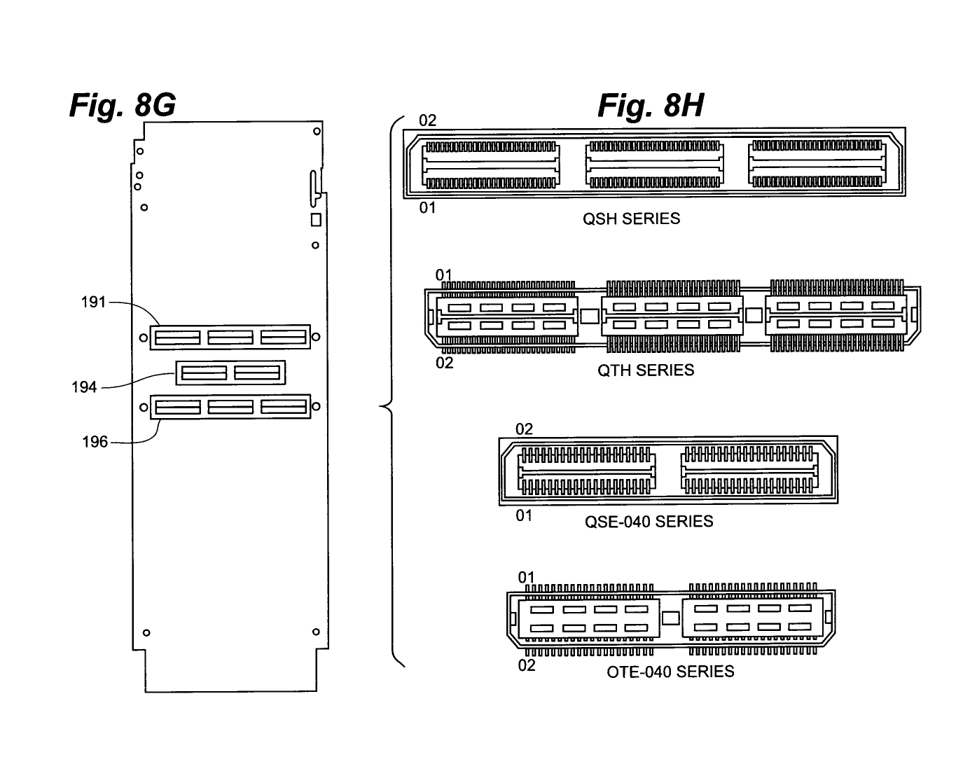

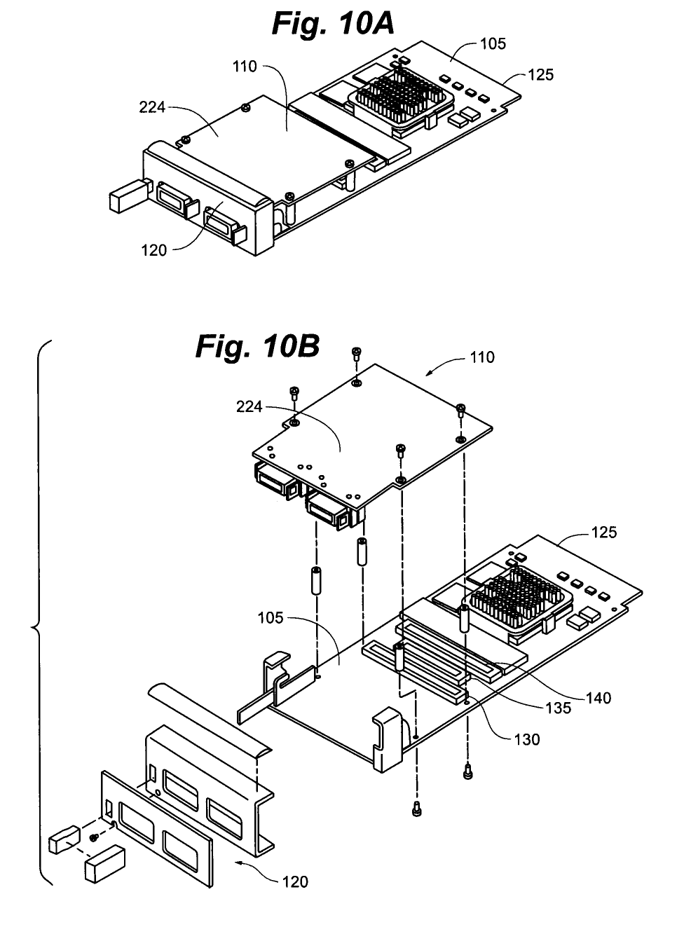

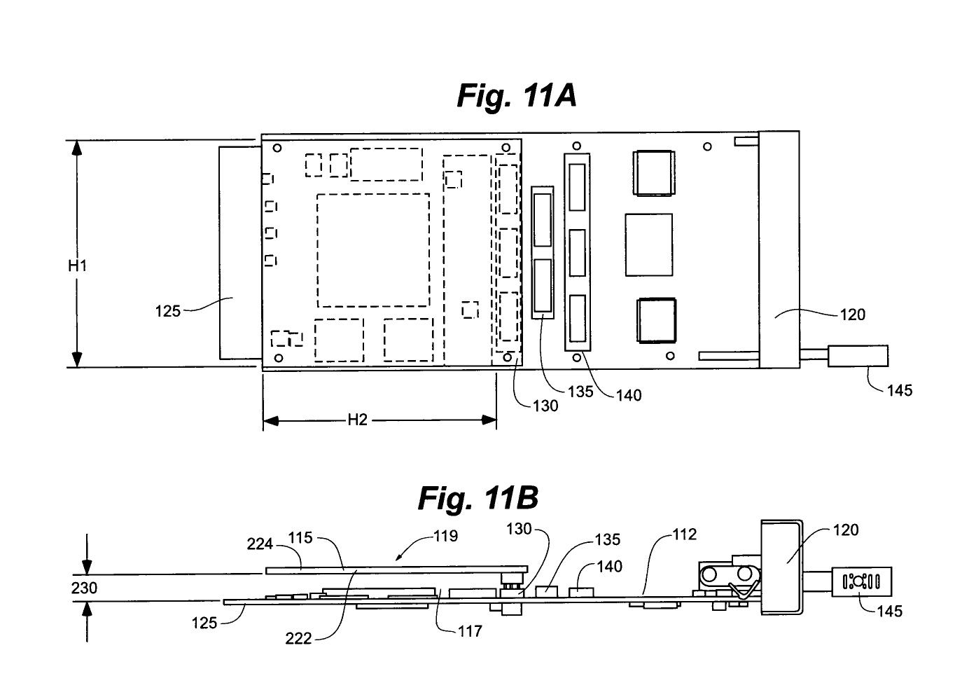

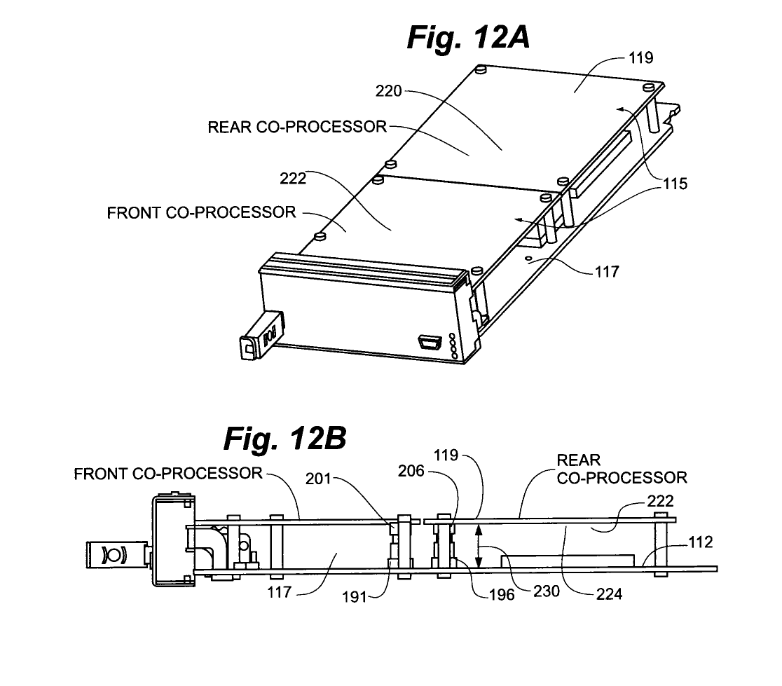

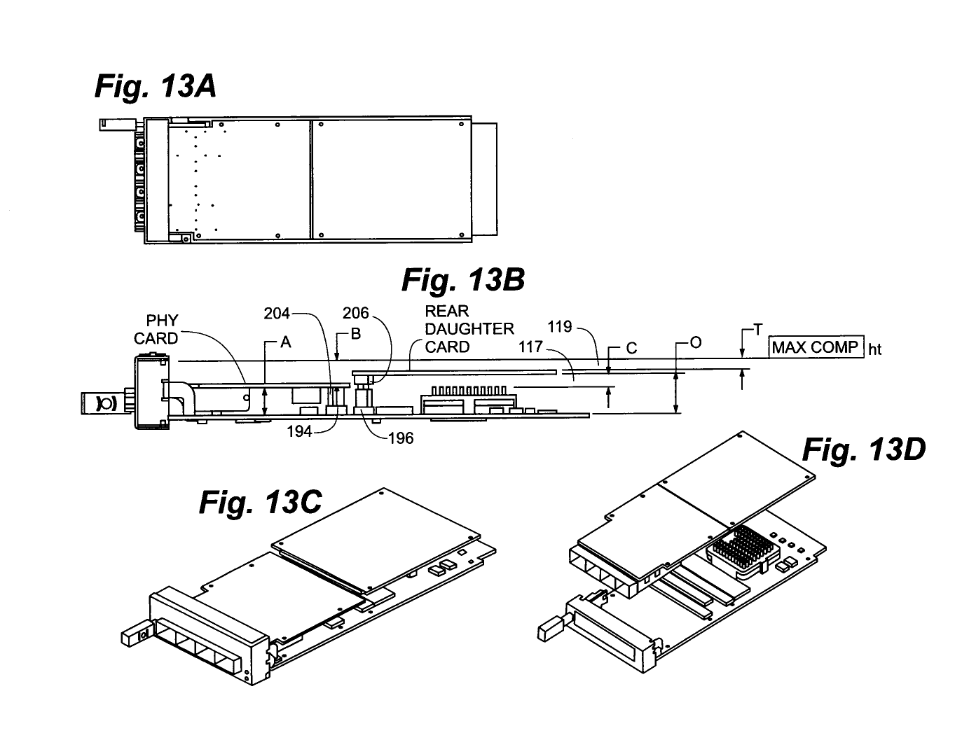

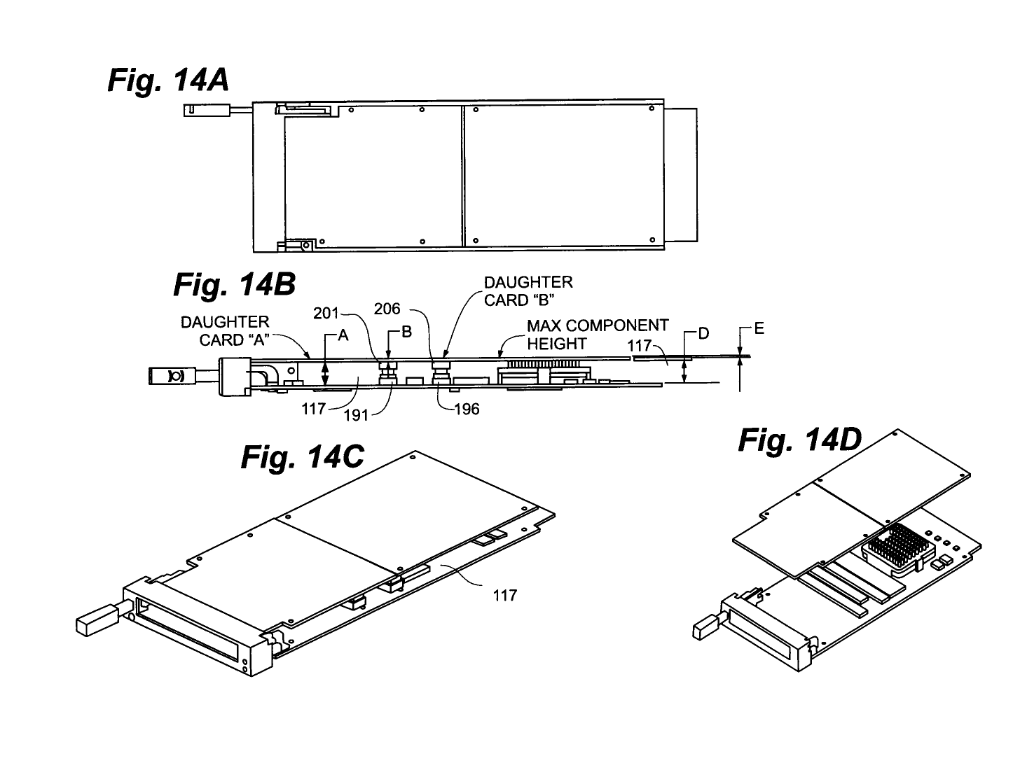

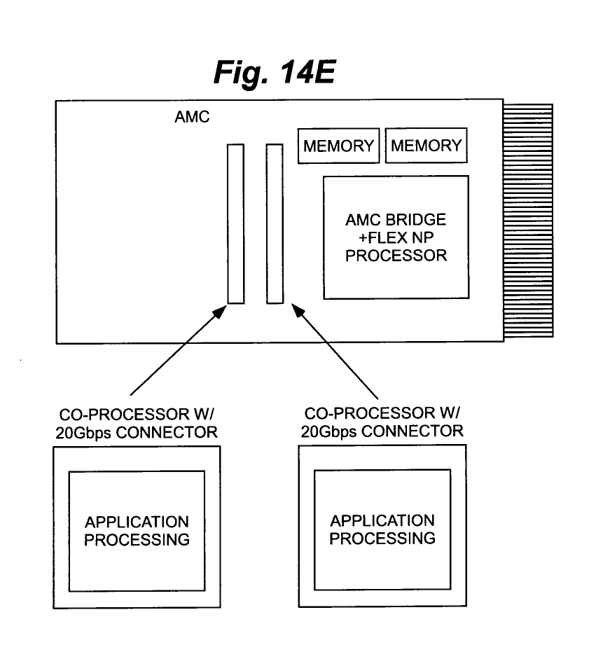

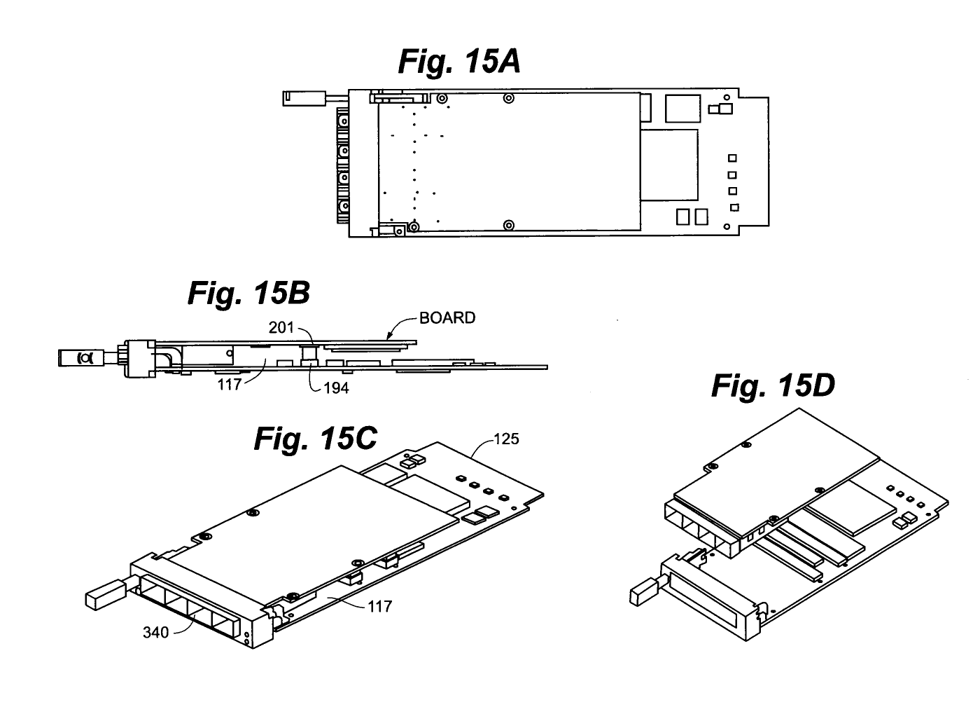

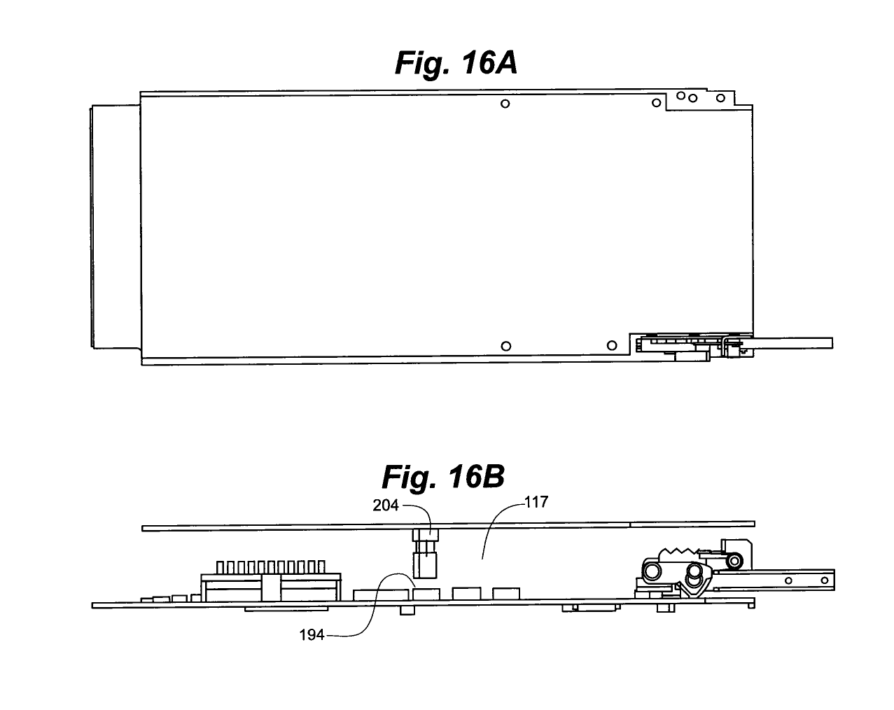

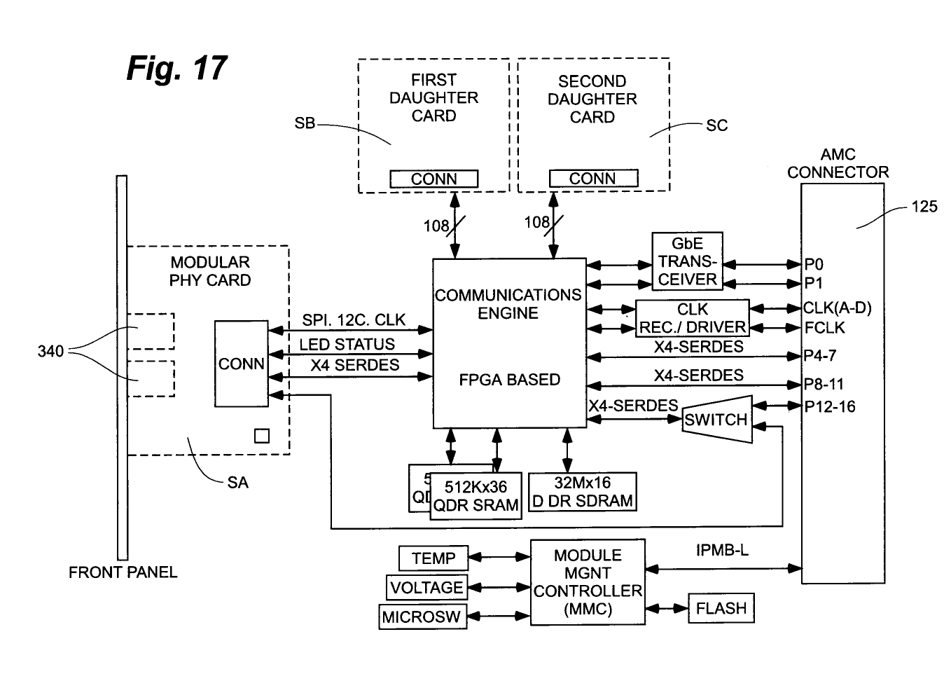

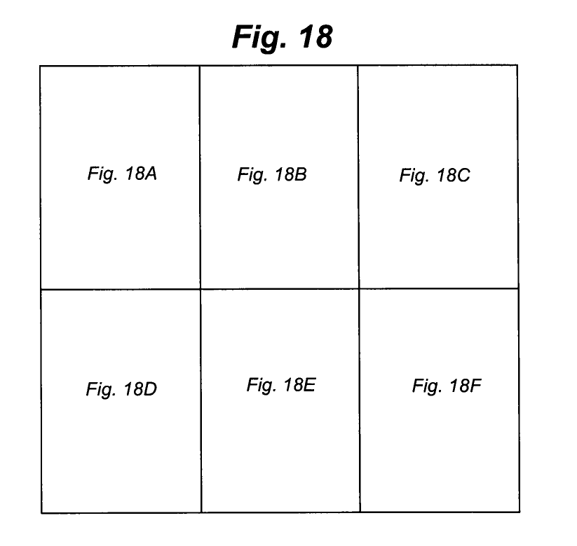

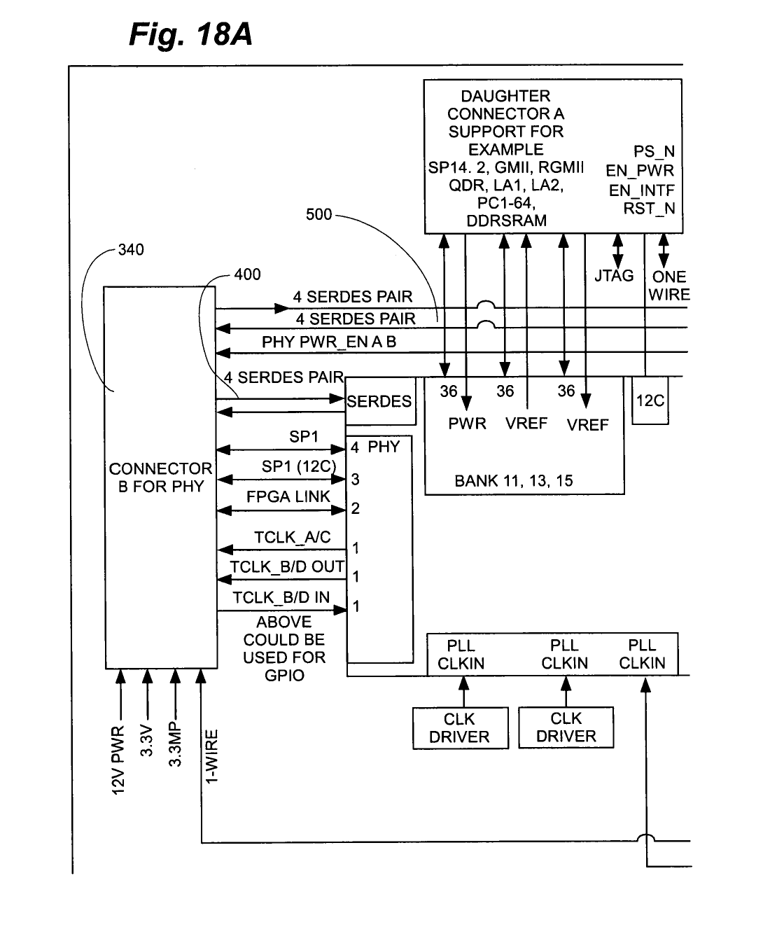

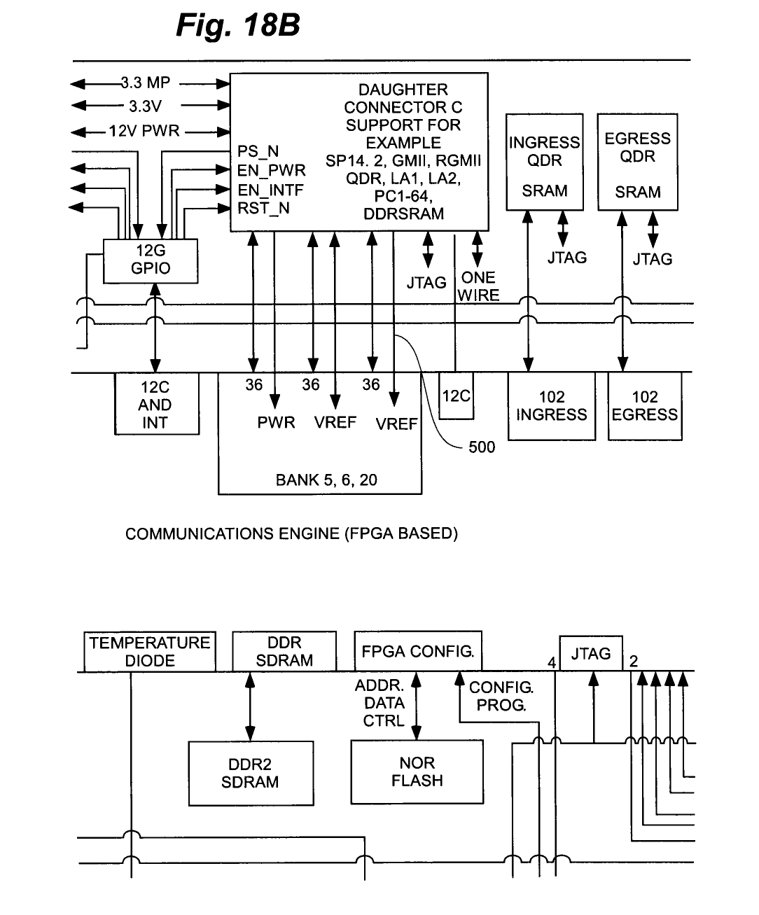

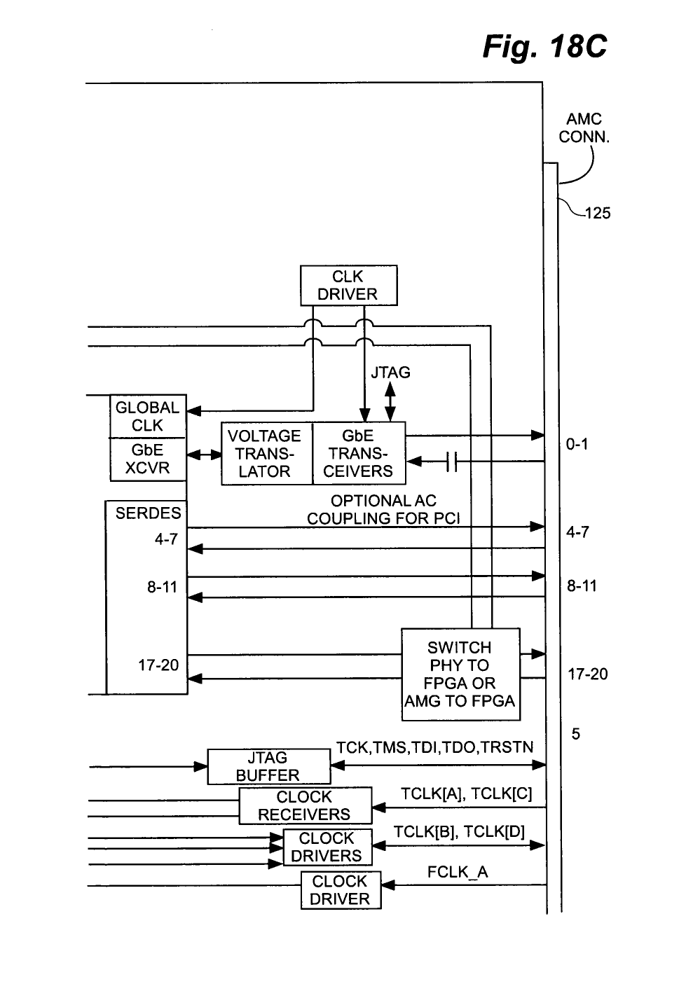

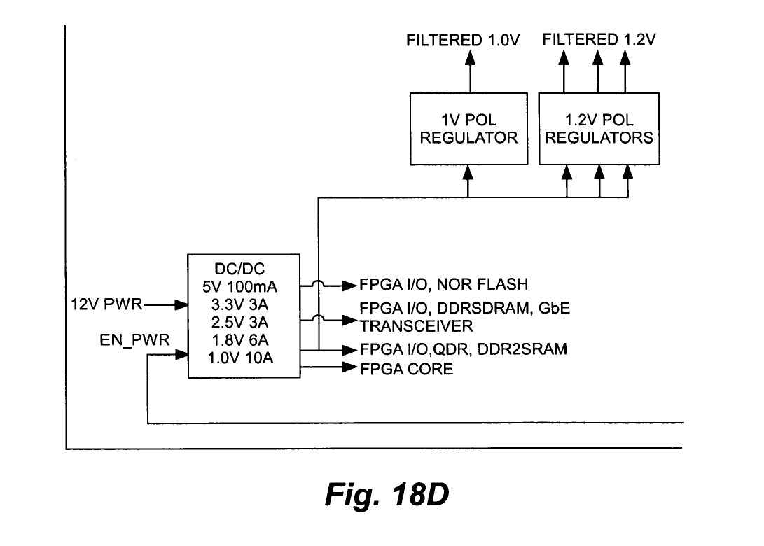

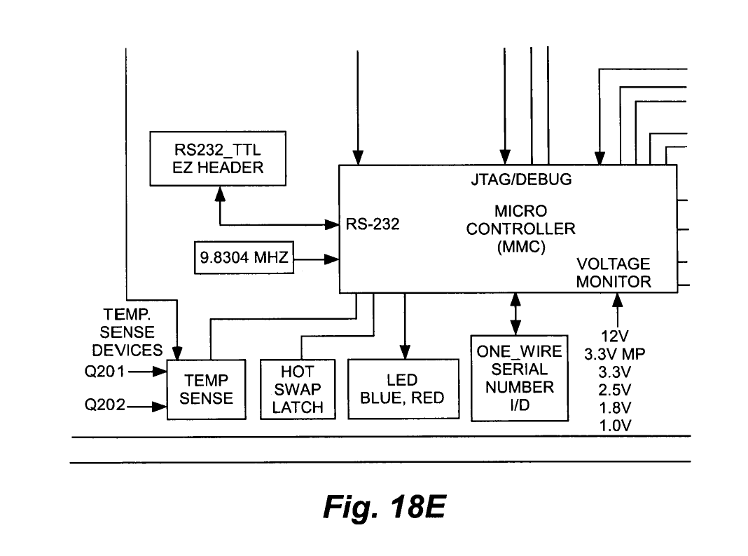

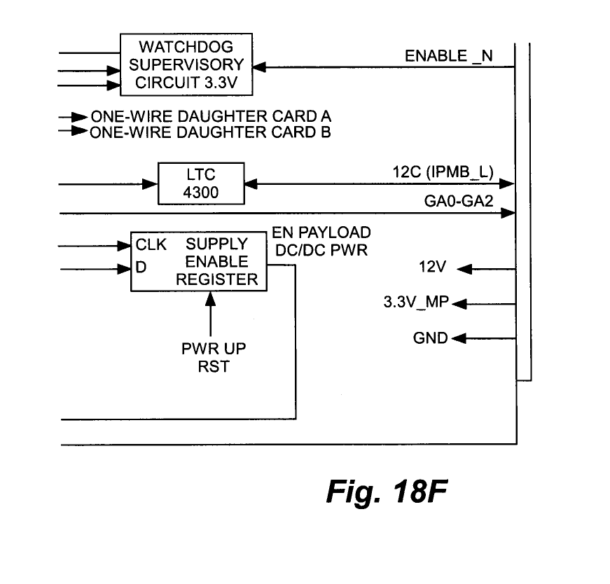

Referring again to the illustrations of FIGS. 7A thru 7D and including additional illustrations of FIGS. 7E and 7F, base board area 112 includes one or more electronic components and wiring 180 and mechanical components 185 disposed thereon. Base board area 114 may also include electronic 180 and mechanical components 185 as illustrated in FIGS. 7G and 7H but the components—mechanical or electrical, must remain substantially within the component volumes 45, 50 associated with respective base board areas 112 and 114 so that the circuit card module 100 is compliant with the AMC specification. Component side_1 35 associated with base board area 112 on the base board 105 is typically the component side on which the electronic components 180 are generally populated. Tall components such as electrolytic capacitors, heat sinks, central processing units with integral heat sink, power modules, connectors and so forth are typically mounted on component side_1 35 (i.e. on base board area 112). Component side_2 40 (i.e base board 114) is the solder side of base board 105 which may be used to mount shallow, low profile electronic components 180 such as resistors, capacitors, chips of a chipset and so forth. Electronic components 180 on the base board area 112, together with any such components on the base board area 114, constitute electronic circuitry 182, which in its entirety delivers the electronic functionality that circuit card module 100 is designed for. Disposed on the base board area 112 and fixedly coupled to the base board 105, is at least one base board connector 190 for coupling with the one or more daughter cards 110, 115. In a specific embodiment illustrated in FIGS. 7A-7F, base board area 112 is provided with first, second and third connectors 191, 194, 196 extending from base board area 112. Each connector 191, 194 and 196 is fixedly attached to the base board 105 at one end thereof and presents a configuration (male/female) for removably mating with at least one counterpart (female/male) connector 201, 204, 206 disposed on a daughter card or cards 110, 115 as best seen in the illustration of FIGS. 8A, 8B, 9A and 9B. The connectors on the base board when mated with appropriate connectors on the daughter cards serve to mechanically align and restrain the base board 105 against movement relative to the daughter card and electrically couple the electronic 180 components and/or circuits with corresponding electronic components/circuits on the daughter card. While specific daughter card functionality may require the use of specific connector types to accommodate the specific electrical connectivity required with the circuitry on the base board 105 to enable specific daughter card functionality, it will be understood that the present invention is not generally limited by the type, number or placement of the connectors 191, 194, and 196 or 201, 204 and 206. In one embodiment, the connectors are right angled connectors that extend outward and perpendicular to the printed circuit board surface area.

For example, FIG. 7E illustrates two connectors instead of the three depicted in FIG. 7A for instance. It will be appreciated that in certain applications, base board 105 may contain all the electronic 180 and mechanical 185 components required to deliver an application-specific functionality and because base board 105, individually and in combination with the daughter cards 110, 115 conforms to the AMC specification, the base board 105 (populated with the required electronic 180 and mechanical 185 components required to deliver the requisite functionality) may be used as an AMC module on a stand-alone basis within the scope of the present invention.

Referring now to FIGS. 8A, 8B, 9A and 9B, there are depicted daughter cards 110, 115 or mezzanine cards according to a general embodiment of the present invention. Each daughter card 110, 115 (alternately daughter board 110, 115) includes a printed circuit board 220 with daughter-card component side 222 (alternately first area of printed circuit board 220)) opposite daughter-card solder side 224 (alternately second area of printed circuit board 220). Daughter component side 222 (and optionally, daughter component side 224) includes one or more electronic components and wiring 183 and mechanical components 187 that together with the electronic components 180 and mechanical components 185 on the base board 105 comprise the electronic circuitry 182 and the mechanicals 184 that cooperate to substantially realize the functionality that circuit card module 100 is designed to provide. In the illustrative embodiment of FIGS. 8A, 8B, 9A, and 9B, daughter component side 222 includes at least one electrical connector 201, 204, 206 designed to removably mate with the one or more electrical connector 191, 194, 196 to mechanically align and hold daughter card 110, 115 relative to the base board 105.

In an exemplary embodiment, upon thus mating daughter card 110, 115 with base board 105 via the electrical connectors on the base board 105 and the daughter card 110, 115, component side 135 (i.e. base board area 112) of the base board faces and is proximate to daughter component side 222 as best illustrated in FIGS. 11B and 12B with a spacing 230 between the two boards. As depicted in the illustrations of FIGS. 8, 9, 10, 11 and 12, both the surface area on which electronic 180 and mechanical components 185 may be mounted and the volume within which these components may reside are substantially increased in the case of circuit module 100. The available surface area is substantially base board area 112 (and optionally base board area 114) and daughter component side 222 (and optionally daughter component side 224) instead of just the base board area 112 (and optionally base board area 114). Besides, the packing density can be substantially improved because components may be mounted on both the daughter card and base board area extents as noted above so as to effectively increase the component fill within allowable volume represented by the spacing 230 thus overcoming the physical and/or operational constraints (e.g. without limitation, component size, thermal and routing requirements, electrical characteristics that detrimentally influence the operation of an adjacently located component, the number of components required and their interconnectedness to effectuate a particular design (example—system memory and CPU proximity for memory latency reduction) and so forth) that may preclude mounting components (mechanical, electrical or both) close proximity to each other so as to maximize packing density on a single surface, such as for example, base board area 112 as will be appreciated by one of skill in the art. The base board and daughter boards described above support the physical partitioning or segmentation of the spatial layout of the electronic and mechanical components that are required to deliver the application specific functionality contemplated for the circuit module 100 into a plurality of sets or groups. By way of example, set 1 may be electronic components 180 and mechanical components 185 on base board 105 and set 2 may be electronic components 183 and mechanical components 187 distributed on one or more daughter cards 110, 115.

Referring now to FIGS. 6A, 6B there is illustrated another exemplary embodiment of the present invention depicting the physical (and functional) partitioning of the spatial layout (functional differentiation) of the electronic 180 (183) and mechanical 185 (187) components/circuitry/devices of the circuit card module 100. FIGS. 6A and 9B, for example, depict a first daughter card 110 and a second daughter card 115 mounted by mating connector 191 on the base board 105 with connector 201 on the first daughter card 110 and connector 196 on the base board 105 with connector 206 on the second daughter card 115. It must be appreciated that the particular connector pair, number of connectors, location of connectors and type of connectors are not limiting of the present invention. The particular configurations shown and described herein are exemplary and are presented by way of facilitating the exposition of the present invention but are not intended to be limiting of the present invention in any way, shape or form.

It must be appreciated that physical partitioning of the spatial layout of the components of the circuit card module 100 by, for example, distributing the components (electrical and mechanical) between the base board and one or more daughter boards, may be partially or totally based on the functionality of the components or aggregation of components included within a physical partition, segment or grouping. Thus, in an exemplary embodiment of the present invention, the circuit modules that comprise the wiring and circuitry of circuit card module 100, such as those circuit modules illustrated in FIG. 5 for instance, are selectively segmented into groups based upon their function or the functionality of aggregates of such circuit modules. Portions of the electronic circuitry 182 that is configurable for specific functionality, for instance, may be segmented by locating it on different printed circuit boards (modular cards) such as, for example, the base board 105 and the daughter boards 110, 115. Such an arrangement supports modularity by allowing the functionality of the electronic circuitry 182 to be distributed on modules that can be replaced by other modules within applicable design limits. Any discussion with respect to electronic functionality also applies to mechanical functionality obtainable using one or more mechanical components. In other embodiments, physical partitioning of the spatial layout of the components need not consider the functionality of the components or aggregation of components. Instead, such a physical partitioning may be based on considerations such as circuit density, maximizing the components deployable within the component volume in accordance with standards, circuit layout constraints and/or mechanical placement constraints etc. It will be appreciated that hybrid partitions may be constructed that feature varying degrees of physical and functional partitioning within a single modular card.

FIG. 17 and FIG. 18 are functional block diagram representations of an exemplary implementation of the circuitry and mechanicals on a circuit card module 100 according to the present invention. Circuit card module 100 may be, for example, a RL-20 Reprogrammable Line Card manufactured by CorEdge Networks, Inc. also referred to as the CEN-RL20™ AMC module (hereinafter the “RL-20”). The RL-20 implements an architecture which may be represented in block diagram form as illustrated in FIGS. 17 and 18. Functional modules shown in the form of rectangular functional block outlines in FIGS. 5, 17 and 18 can represent an application-specific, functional segmentation of circuitry and mechanicals of circuit module 100. In one illustrative embodiment, each such functional segmentation—represented by the dashed-line rectangular blocks in FIG. 17, may be located on separate daughter cards 110, 115. The base board 105 includes circuitry 300 and mechanicals 305 that cooperate to provide common services (alternately base module functionality) needed by any system targeted to run on circuit module 100. The common services may be necessitated, for instance, for compliance with applicable standards or specifications. Alternately, circuitry 300 and mechanicals 305 may represent functional blocks common to all systems designed to run on circuit module 100. An exemplary Base module 105, exemplified for instance, by the architecture of the RL-20 and illustrated in part by FIGS. 7A-7H, may provide a fully-compliant Module Management Controller (MMC) and associated functional modules including temperature and voltage sensors, hot swap latch, one-wire serial interface, voltage monitor and an Intelligent Platform Management Interface (IPMI)—the IPMB (Intelligent Platform Management Bus/Bridge) (an enhanced implementation of I²C (inter-integrated chip)).

In a specific embodiment, such as the one exemplified by the RL-20 for instance, at the core of the MMC is a Microcontroller, (such as the ColdFire® microprocessor manufactured by Freescale Semiconductor, Inc., of Texas, USA) which manages local resources such as hot-swap microswitch, watchdog, status LEDs, temperature sensors, and voltage sensors as well as a serial console. The microcontroller may be a 32-bit device belonging to the set of Reduced Instruction Set Computing (RISC) microprocessors, operating at a frequency of 66 MHz, offering high performance and low power consumption. The microcontroller may feature on-chip memories connected tightly to the processor core including, for instance, up to 256 Kbytes of flash memory and 32 Kbytes of static random access memory (SRAM). Another feature of the present invention, which may be illustrated using the RL-20 base board architecture, is the improved circuit packing density made possible. Base board 15 of the illustrative embodiment may have one or more areas on component side_1 35 or component side_2 40 that are intentionally kept free of wiring or circuitry. FIG. 7A depicts one such “keep out area” 320 on component side_1 35 of the RL-20 board within which component placement is prohibited because by design it is intended to locate a heat-sink or equivalent device. Despite this restriction, the present invention discloses a MMC (i.e. the microcontroller) 310 located on component side_2 40 opposite keep-out area 320 and a daughter card 110 located above the heat sink in a mezzanine position as illustrated in FIG. 7H. Such a placement option substantially reduces any negative impact of the keep-out area 320 on circuit density of the circuit module 100. According to an illustrative embodiment of the present invention, the base module 105 is generally configured with at least one on-board connector 191 (194, or 196) which allows it to be electrically and mechanically coupled to one or more daughter cards. In one embodiment, illustrated in FIGS. 8G and 8H, exemplary connectors 191, 194 and 196 in accordance with the present invention may be substantially perpendicular to a mounting surface of the base module 10 and configured to receive and mate with a paired connector located on a daughter card such that base board area 112 of the base module 105 is located in spaced apart, parallel and facing daughter component side 222 in the manner of the illustration of FIGS. 6A, 6B, 7H, 9B, 10H, 11B, 12A, 12B, 14B, 15C and 16B for instance. FIGS. 8G and 8H depict exemplary connectors according to one embodiment of the present invention, as shown in the figures the connectors may be a QSH, QTH or QSE series connector manufactured by SAMTEC, Inc., of IN USA. Other connectors and connection modes between the base module 105 and one or more daughter cards 110, 115 may be used within the scope of the present invention.

It must be appreciated that the base module 105 may be configured to provide more than just the minimal functionality as noted above. As shown in the illustrations of FIGS. 7A-7H. FIGS. 7A-7H and FIGS. 17-18, the base module 105 of an exemplary circuit card module 100 represented by the RL-20 AMC module, comprises, in addition to the MMC described above, a Field Programmable Gate Array (FPGA) based Soft-Logic Communication Engine 325, Quad Data Rate (QDR) memory (2 MB ingress and egress) 330, a DDR2 SRAM, a NOR Flash chip, DC-DC converter and point-of-load (POL) regulators. The Soft-Logic Communication Engine 325 maybe, for example, a Virtex™-5 FPGA manufactured by Xilinx, Inc., of San Jose Calif. In an exemplary configuration, the CEN-RL20™ comprises a base module 105 with optional daughter card implementations 110, 115 and is customizable to support 20 Gbps wire speed, low latency hardware implementations, upwards of 16 high-speed SerDes interfaces to AMC and front panel connector, upwards of 8 high-speed SerDes interfaces to PHY card connectors, custom, third party or off-the-shelf IP support, I/O, processing, and functional customization. The software communications engine is capable of supporting I/O, DSP, NPU, and CPU implementations for a number of applications. In specific implementations, it can provide high-speed and programmable SerDes links to the AMC connector 125 and front panel I/O connectors 340 of the AMC module more clearly illustrated in FIGS. 15C, 17 and 18. The software communications engine can utilize off-the-shelf Intellectual Property (IP) to support a wide variety of backplane and front panel interfaces including MAUI, PCI Express, Serial RapidIO, SONET, etc in various system environments including the exemplary MicroTCA system 60 depicted in FIG. 4A. The CEN-RL20™ is used for illustrative purposes because it features specific embodiments of the present invention but the scope of the present invention is not limited to the CEN-RL20™ or any particular AMC module.

Another feature of the present invention is that it enables functional customization of the circuit module 100. This feature may be illustrated by the CEN-RL20, which can support one I/O PHY Module and at least one Host Daughter Card. The daughter cards may be configured to provide all or part of the electronic and mechanical functionality not otherwise provided the base module 105. FIGS. 6A, 6B, 7A thru 7D, 8A, 8B, 10A and 10B are illustrative of functional customization of input/output (I/O) processing in accordance with the present invention. FIGS. 6A and 6B depict a perspective view and a side view of a circuit card module 100 according to a general embodiment of the present invention. Circuit card module 100 includes a base card 105, best illustrated in FIGS. 7A-7D and a modular I/O PHY daughter card 310, best illustrated in FIGS. 8A and 8B. The modular I/O PHY card 110 attaches via a connector 204 to a high-speed connector 194 on the base board 105 (alternately “base module”) through which either 4 or 8 SerDes links from the communications engine FPGA are routed. Power, clock, SPI, and I2C signals are also provided to the PHY card. This is illustrated in FIGS. 17 and 18 wherein the functional blocks labeled 1) Connector B, 2) AMC connector 125 and their interconnections with the communications engine (FPGA) represents one implementation of the front-panel customization through the optional I/O PHY card 110 in accordance with the present invention.

For ease of disclosure, the functional customization is described with reference to a communication engine based on the Virtex™-5 FPGA. It must be emphasized that the invention is not limited by the use of the specific FPGA or any FPGA. Other architectures based on general purpose processors, special purpose processors, Application Specific Integrated Circuits (ASICs), Complex Programmable Logic Devices (CPLDs), and other processing architectures may be used without limiting the scope of the present invention.

The communications engine of FIGS. 17 and 18 provides up to sixteen multi-gigabit transceivers (“MGTs”) 400 as shown in the functional block diagram of FIG. 18. These transceivers are capable of running from 100 Mbps to 3.2 Gbps and support all of the major serial protocols including 1000 Base-X, PCI Express, XAUI, and Serial RapidIO. In the illustrated embodiment, the 16 MGTs may be used to implement two high speed lanes for 1000BASE-BX Ethernet, upto 12×AUI 3.125 Gb/s lanes, upto 12 8 PCI Express 2.5 Gb/s lanes, or upto 8 PCI Express 2.5 Gb/s lanes extending to/from the Soft-Logic Communication Engine to the PHY connector 194 on the base board 105. In the specific embodiment of FIGS. 17 and 18, 12 SerDes lanes are provided to ports 4-15 of the AMC connector and 4 SerDes lanes to the PHY connector 194.

In another specific embodiment, 8 SerDes lanes may be provide to AMC ports 4-11 and 8 lanes to the PHY connector 194. Other partitions of the SerDes lanes may be used within the scope of the present invention. For example, FIG. 18 depicts a switch which allows switching four SerDes lanes from their PRY connector—FPGA interconnections to the AMC connector—FPGA interconnections. The modular I/O PHY card may enable a variety of front panel access options, including Quad SFPs, single/dual CX-4s and XFP versions for multiple 1 Gbps and 10 Gbps Ethernet copper and fiber interfaces, Octal SFPs and SONET.

In a particular embodiment, the communications engine may provide two standard PHY modules—Quad SFP module and a Dual CX4 module best illustrated in FIGS. 8C thru 8F. The Quad SFP Module (designated “CEN-PHY-SFP4”) provides four Small Form-Factor Pluggable (SFP) cages that can accommodate either copper or optical SFP transceivers for supporting GbE, Fibre Channel, or other serial interconnect technologies. In an exemplary implementation, the four SFP channels on the I/O PHY card (or module) are connected via PHY connector 194 to the SerDes ports of the Soft-Logic Communication Engine on the base module 105 as seen in FIG. 18. I2C signals from the Management Controller Hub (MCH) (see FIG. 4A) base module are routed to the Quad SFP Module and are logically translated to provide control lines to each of the four SFP channels. A serial EEPROM may also be provided for pre-loading board configurations. In another exemplary implementation, the Dual CX4 Module provides two 10 Gbps front panel interface that connect seamlessly to Infiniband or 10 GbE copper cable assemblies. By implementing XAUI-to-CX4 retimers, longer distances over copper cables can be achieved. I2C EEPROMs attached to each re-timer provide adjustable amplitude and pre-emphasis levels in order to optimize the signaling to meet application requirements. Power and management signals may also be routed to the CX4 connectors which enable support for external CX4-to-XFP adapters. In order to get full functionality of both CX4 connectors, eight SerDes channels of the communications engine may be routed to the PHY Module 194 for connection through connector 204 to the I/O PHY card 110 for instance. FIGS. 8A and 8B provide a perspective view of two different implementations of the I/O PHY daughter cards 110 (alternately, I/O modules, PHY card or I/O PHY card). Each I/O PHY daughter card includes a mechanical module featuring one or more mechanical connector sockets that are positioned proximate the front panel 122 (upon mating PHY connector 204 with PHY connector 194) for interconnection with external I/O devices as seen in FIGS. 7H, 10A, 13A, 13C, and 15D. FIG. 10B is an exploded perspective view of the I/O PHY daughter card 110 in relation to the base module 105. Both the aforementioned PHY cards include a printed circuit board with a first surface area 222 representing a component side_1 and an opposed second surface area 224 representing a component side_2 or solder side. A connector 201 is located on first surface area 222 for interconnection with a mating connector on the base module 105 such that surface area 222 is disposed adjacent base board area 112 in a spaced apart substantially parallel relationship to it as illustrated, for example, in FIGS. 10A, 10B, 13C, and 15C. Each PHY card is provided with a mechanical module 335 (340) which includes one or more I/O connectors 320 shaped and designed to interface with selected external connectors/devices transferring communications according to a predefined communication protocol.

FIGS. 8A and 8B illustrate exemplary I/O PHY cards according to the present invention—the CEN RL-20 4 Port GbE Daughter Card and the CEN RL-20 Non-Module Cx-4 10 GbE PHY Card respectively, both manufactured by CorEdge Networks, Inc. of Minneapolis, Minn., USA. The CEN RL-20 4 Port GbE Daughter Card of FIG. 8A is provided with a Quad SFP I/O cage 335 and the CEN RL-20 Non-Module Cx-4 10 GbE PHY Card is provided with dual CX4 I/O connectors 340. When a PHY card is mated with the base module 105 via connector 204 on the card, the I/O connectors 320 are located adjacent suitably designed apertures in the face panels for facilitating connection with the external I/O cables and devices. The face panels may be shaped and designed with appropriate apertures to locate and support the mechanical modules on the PHY cards as is clearly the case with face panels 122, 123 and 124 of FIGS. 7B, 7C and 7D respectively. Other configurations of face panels, mechanical connectors or I/O protocols may be accommodated within the scope of the present invention.

Referring now to FIGS. 6B, 7I, 11B, 1A, 12B, 13B, 14A-D, 14E, 16B and FIGS. 17 and 18, there is illustrated another feature of the present invention in the form of daughter cards 115. While at least a portion of the I/O PHY daughter card 110 extends from a connector of the base board 105 to the front panel 120 (specialized as 122, 123 and 124 for example) as described above, the present invention also provides for one or more daughter cards 115 each of which may extend from connectors 191, 196 on the base board 105 towards the card edge connector 125 at the rear of the board card 105 and away from the front panel as shown in FIGS. 6A, 6B, 11B, 12B, 13D and 14B. In a particular embodiment illustrated in FIG. 12B for example, the daughter card 115 may extend from a connector 196 on the base card to the front panel but without presenting I/O interfaces at the front panel.

FIG. 16B depicts another embodiment of the present invention wherein the base board 105 includes a single daughter card connector 196 which mates with a connector 204 on a single daughter card 115. Daughter card 115 may extend substantially from the front panel 120 to the card edge connector 125. The base board module 105 illustrated in FIGS. 12B and 14B has dual daughter card connectors 191 and 196 to mate with the two daughter cards which in the illustrated embodiment provide rear and front co-processor support to the base module 105. Daughter card connectors 191 and 196 correspond to Daughter connector A and Daughter Connector C in functional block diagrams of FIG. 18 respectively. To understand the relationship between the daughter cards 115 and the base module 105, it is necessary to expose the details of the daughter card connector 201, 206 and the FPGA based communications engine as set forth in the exemplary embodiment of FIG. 18. However, to avoid over complicating the present disclosure only those details of the FPGA-daughter connector are presented as area needed to understand the present invention.

Besides the sixteen multi-gigabit transceivers (“MGTs”) in the functional block diagram of FIG. 18 and discussed above in connection with the I/O PHY card, the FPGA based communications engine also includes programmable input/output blocks (I/O blocks) designated BANK in FIG. 18, memory, such as QDR SRAM (ingress and egress) pins, DDR SRAM pins, JTAG interface pins, and an I2C interface pins to name a few. Each I/O block (“BANK”) comprises several configurable I/O pins 420 from the FPGA which are routed to the daughter card connectors A and C to enable a plurality of interfaces including, for example, SPI4.2, GMII, RGMI, QDR, LA1, LA2, PCI-64, DDR SRAM, and others.

Additional details of the pinout for the Virtex-5 FPGA are described in “Virtex-5 Packaging and Pinout Specification” UG195 (v3.2) published Aug. 14, 2007, available from www.xilinx.com/bvdocs/userguides/ug195.pdf which is incorporated by reference herein in its entirety. One of the features of the present invention is a control on the power budget of the FPGA based on the daughter card 115 that is in use. Typically, a minimum of two voltages are needed to power FPGAs: one for the “core” (1.0V to 2.5V typical) and one for the “I/Os” (3.3V typical). Many FPGAs also require a third low-noise, low-ripple voltage to provide power to the auxiliary circuits. Typical voltages are 2.5V or 3.3V depending on the individual FPGA family. Operating current for each of these voltages is not fixed and depends upon many application-related factors, such as FPGA speed, capacity utilization, and the like. Operating current can vary from as low as 100 mA to as high as 20 A. Conventionally, the main power supply for the FPGA's internal core logic circuits such as the Configurable Logic Blocks (CLBs) and programmable interconnect is provided from VCCINT.

In the present invention, this power is supplied from the base board 105 as depicted in FIG. 18. Typical VCCINT voltages include: 1.2, 1.5, 1.8, or 2.5V, depending upon the individual FPGA family. Each of the I/O banks have their own set of VCCO power supply pins that power the output drivers. The voltage on the VCCO pin determines the voltage swing of the output signal from the particular I/O bank. Typical VCCO voltages include: 1.5, 1.8, 2.5, 3.0, or 3.3V, depending upon the individual FPGA family. If a particular I/O bank uses a differential low voltage I/O standards for signaling, it is necessary to supply an input reference voltage (VREF). The VREF pins collectively supply an input reference voltage, for any low voltage differential standard implemented in the associated I/O bank. Typical VREF voltages include: 0.75, 0.8, 0.9, 1.0, 1.25, 1.32, or 1.5V, depending upon the individual FPGA family. One of the features of the present invention is that the end-user may architect the daughter card for application-specific purposes. Each daughter card may differ in the internal digital logic voltage as well as the low voltage I/O standard it uses for signaling. One of the features of the present invention is that the daughter card provides the appropriate VCCO power to the specific I/O bank of the FPGA that the daughter card is coupled to via the daughter card connector 201, 206. Using a separate low power line, the daughter card feeds the VCCO voltage to a voltage divider circuit to generate a reference voltage VREF which is supplied to the input VREF pin of the FPGA. The reference voltage VREF and the VCCO voltage supplied to a specific I/O bank by a daughter card are substantially the same as the values of these parameters the FPGA is configured to expect from the specific I/O bank. In another embodiment, the FPGA may be configured to expect predefined values of VCCO power and VREF voltages at selected I/O banks. Depending on the internal digital logic of a daughter card and the signaling standard it uses, it can be selectively connected, via the daughter card connector, to that I/O bank at which the VCCO power and VREF voltages expected by the FPGA's configuration closely match the VCCO power to VREF voltage the daughter card is designed to supply.

The FPGA of the illustrative embodiment of FIGS. 17 and 18 is coupled to an external nonvolatile memory (designated “NOR FLASH” in FIG. 18) which stores and provides a configuration bitstream to configure the FPGA, namely, to program one or more configuration memory cells to configure CLBs and I/O banks. In an alternate embodiment, the configuration of the FPGA may be defined by entering programming data through a JTAG port using a JTAG controller as is well known in the art. In other embodiments, the MMC (microcontroller) can be made to take the control of FPGA re-configuration during boot-up and direct the specific resource from which information may be obtained for configuring the FPGA. This resource may reside on the daughter card, on a serial flash device located external to the system and accessible via the I2C interface, through the GPIO, directly from the JTAG port, or any other data paths using methods well known in the art. In effect, the daughter card may encapsulate and define the configuration of the FPGA instead of the configuration being obtained from a data repository on the base board 105. In the particular embodiment of FIG. 18, the circuit module card 100 is devoid of any pre-programmed FPGA RTL and can be fully customized by the end user.

In alternate embodiments, several pre-programmed versions using the patent-pending BitStream Processor may be utilized within the scope of the present invention to enable various 20 Gbps line or NPU card solutions. The BitStream Processor is a Omni-protocol, wire-speed packet processing engine which supports multiple protocols, including Ethernet, SONET, and ATM. The processor decodes incoming frames, generates look-up keys on the fly, and parses the outgoing packets at upwards of 10 Gbps wire speeds and with low latency. Further details are provided in U.S. Patent Publication # 2007006748, “Omni-Protocol Engine For Reconfigurable Bit-Stream Processing In High-Speed Networks” assigned to the assignee of the present invention, the contents of which are incorporated herein it their entirety.

One feature of the present invention, best illustrated in functional block diagram form of FIG. 17, the circuit module of the present invention may comprise a FPGA-based Advanced Mezzanine Card (AMC) (such as the CEN-RL20™ for example), that is customizable to support a wide range of user requirements. I/O flexibility may be provided by programming the FPGA (remotely or locally) to implement logic to support a plurality of applications. For instance, the FPGA may be a Xilinx Virtex-5 FPGA customized to provide a plurality of high-speed and programmable SerDes links to the AMC connector and front panel I/O connectors 340 (and SA) of FIG. 17. In the illustrative embodiments, the circuit-card module is configured to support at least one releasably coupled PHY module and at least one releasably coupled host daughter card. Front panel I/O customization may be enabled through optional PHY modules. Optionally, by changing the host daughter cards, additional advanced I/O or data processing, such as security, network processing and/or look-up memory operations, may be performed. By using off-the-shelf Intellectual Property (IP), a wide variety of backplane (i.e. at the AMC connector of FIG. 17) and front panel interfaces (i.e. at the front panel in FIG. 17) can be supported including XAUI, PCI Express, Serial RapidIO, SFP, CX4 and so forth.

In other embodiments, the FPGA may be replaced by, emulate or be augmented with one or more of a digital signal processor (DSP), Network Processor Unit (NPU), Central Processing Unit (CPU), an Application Specific Integrated Circuit (ASIC) or other such devices or combinations thereof (collectively “compute engines”). The aforementioned compute engines can be configured for remote or local programmability. In one embodiment, the compute engine may be configured to implement I/O virtualization. In this embodiment, when any of the other modules (such as those depicted in FIG. 4A) request an I/O operation, these requests are sent to the circuit-module of the present invention. The compute engine of the present invention may be configured to implement a virtual I/O environment that enables a single PHY to be logically managed as multiple virtual I/O resources. When an I/O request is received, one of the virtual I/O resource may be dynamically configured to exclusively service the specific I/O needs of the particular module of the communication system originating the I/O request. A similar implementation may be employed in respect to the backplane interface in respect to the communication protocol, bandwidth and other characteristics requested by a particular module in the communication system. In effect, the circuit-module of the present invention enables programmable customization of I/O services and I/O connectivity provided to modules in the communication system.

One of skill in the art will readily recognize that other functional modules depicted in the functional block diagram of FIG. 18 may be removed from the base board 105 and onto one or more daughter cards to enable advanced processing and/or additional memory, I/O solutions including RF interfaces, GPON interfaces, and security packet inspection. Interfaces such as SPI4.2, native memory, or other application-specific implementations are also possible within the scope of the present invention. It should also be appreciated that the exemplary embodiment or exemplary embodiments are only examples, and are not intended to limit the scope, applicability, or configuration of the invention in any way. Rather, the foregoing detailed description will provide those skilled in the art with an enabling disclosure for implementing the exemplary embodiment or exemplary embodiments. It should be understood that various changes can be made in the function and arrangement of elements without departing from the scope of the invention as set forth in the appended claims and the legal equivalents thereof.

1. An apparatus comprising reconfigurable, reprogrammable, modularized standards compliant modules with increased circuit and functional density substantially as shown and described.

2. A method for providing reconfigurable, reprogrammable, modularized standards compliant modules with increased circuit and functional density substantially as shown and described.

3. A system for providing reconfigurable, reprogrammable, modularized standards compliant modules with increased circuit and functional density substantially as shown and described.
